(19) United States
(12) Patent Application Publication
(10) Pub. No.: US 2025/0105109 A1
(43) Pub. Date: Mar. 27, 2025

(54) SEMICONDUCTOR DEVICE

(71) Applicant: Rohm Co., Ltd., Kyoto-shi (JP)

(72) Inventors: Kaito INOUE, Kyoto-shi (JP); Masaaki MATSUO, Kyoto-shi (JP)

(21) Appl. No.: 18/974,221

(22) Filed: Dec. 9, 2024

Related U.S. Application Data
(63) Continuation of application No. PCT/JP2023/017927, filed on May 12, 2023.

(30) Foreign Application Priority Data
Jun. 14, 2022 (JP) 2022-095937

(51) Int. Cl. H01L 23/495; H01L 23/10

(52) U.S. Cl. CPC H01L 23/49568; H01L 23/10

(57) ABSTRACT

A semiconductor device includes an insulating layer, a conductive layer, a heat dissipation layer, a semiconductor element, and a bonding layer. The conductive layer includes an obverse surface facing away from the insulating layer in a first direction and is bonded to the insulating layer. The heat dissipation layer is located opposite to the conductive layer with respect to the insulating layer and bonded to the insulating layer. The semiconductor element is bonded to the obverse surface. The bonding layer bonds the obverse surface and the semiconductor element. The conductive layer is formed with a recess that is recessed from the obverse surface. The bonding layer includes a first portion located between the semiconductor element and the recess as viewed in the first direction, and the first portion covers the obverse surface.

### TECHNICAL FIELD

The present disclosure relates to a semiconductor device.

### BACKGROUND ART

JP-A-2016-162773 discloses an example of a semiconductor device (power module) that includes a plurality of semiconductor elements bonded to a conductor layer. The semiconductor elements are bonded to the conductor layer via a solder layer. The semiconductor elements are thus mounted on the conductor layer.

In the semiconductor device disclosed in JP-A-2016-162773, when the semiconductor elements are bonded to a conductor layer, the positions of the semiconductor elements relative to the conductor layer may shift due to the spreading of the solder layer. When such positional shift of each semiconductor element is large, conductive bonding of a wire or the like to each semiconductor element takes a longer time, which is not desirable. Therefore, it is desired to improve the accuracy in the bond positions of the semiconductor elements to the conductor layer.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2 as seen through the sealing resin.

FIG. 4 is a bottom view of the semiconductor device shown in FIG. 1.

FIG. 5 is a front view of the semiconductor device shown in FIG. 1.

FIG. 6 is a right side view of the semiconductor device shown in FIG. 1.

FIG. 7 is a sectional view taken along line VII-VII in FIG. 3.

FIG. 8 is a sectional view taken along line VIII-VIII in FIG. 3.

FIG. 9 is a partial enlarged view of FIG. 3, showing a plurality of first elements and the nearby portions.

FIG. 10 is a sectional view taken along line X-X in FIG. 9.

FIG. 11 is a partial enlarged view of FIG. 10.

FIG. 12 is a partial enlarged view of FIG. 3, showing a plurality of second elements and the nearby portions.

FIG. 13 is a sectional view taken along line XIII-XIII in FIG. 12.

FIG. 14 is a partial enlarged plan view corresponding to FIG. 9, showing a semiconductor device according to a first variation of the first embodiment of the present disclosure.

FIG. 15 is a partial enlarged plan view corresponding to FIG. 9, showing a semiconductor device according to a second variation of the first embodiment of the present disclosure.

FIG. 16 is a partial enlarged plan view corresponding to FIG. 9, showing a semiconductor device according to a third variation of the first embodiment of the present disclosure.

FIG. 17 is a partial enlarged sectional view corresponding to FIG. 11, showing a semiconductor device according to a fourth variation of the first embodiment of the present disclosure.

FIG. 18 is a perspective view of a semiconductor device according to a second embodiment of the present disclosure.

FIG. 19 is a plan view of the semiconductor device shown in FIG. 18.

FIG. 20 is a plan view of the semiconductor device shown in FIG. 18, as seen through the sealing resin.

FIG. 21 is a front view of the semiconductor device shown in FIG. 18.

FIG. 22 is a right side view of the semiconductor device shown in FIG. 18.

FIG. 23 is a left side view of the semiconductor device shown in FIG. 18.

FIG. 24 is a bottom view of the semiconductor device shown in FIG. 18.

FIG. 25 is a partial enlarged view of FIG. 20.

FIG. 26 is a partial enlarged view of FIG. 20.

FIG. 27 is a sectional view taken along line XXVII-XXVII in FIG. 20.

FIG. 28 is a sectional view taken along line XXVIII-XXVIII in FIG. 20.

FIG. 29 is a sectional view taken along line XXIX-XXIX in FIG. 20.

FIG. 30 is a sectional view taken along line XXX-XXX in FIG. 20.

FIG. 31 is a partial enlarged view of FIG. 25, showing one of a plurality of first elements and the nearby portions.

FIG. 32 is a sectional view taken along line XXXII-XXXII in FIG. 31.

FIG. 33 is a partial enlarged view of FIG. 25, showing one of a plurality of second elements and the nearby portions.

FIG. 34 is a sectional view taken along line XXXIV-XXXIV in FIG. 33.

### DETAILED DESCRIPTION OF EMBODIMENTS

The following describes preferred embodiments of the present disclosure in detail with reference to the drawings.

### First Embodiment

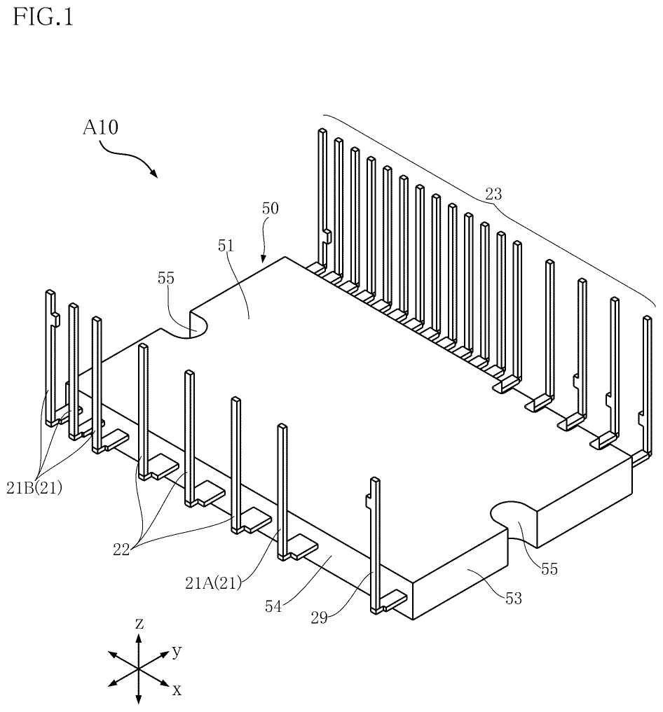

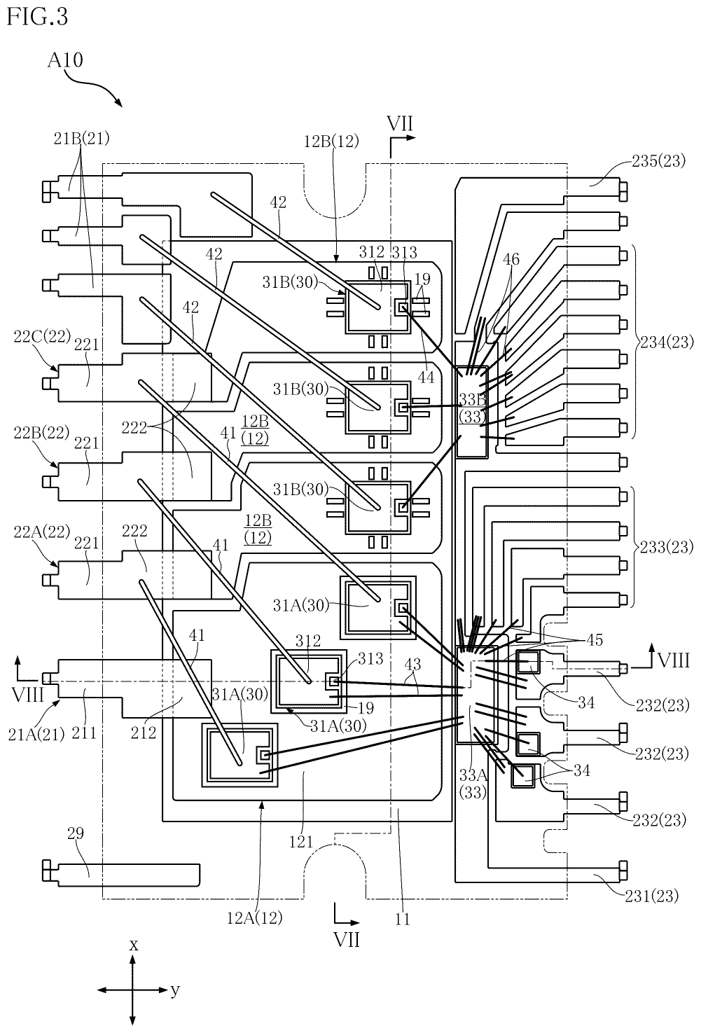

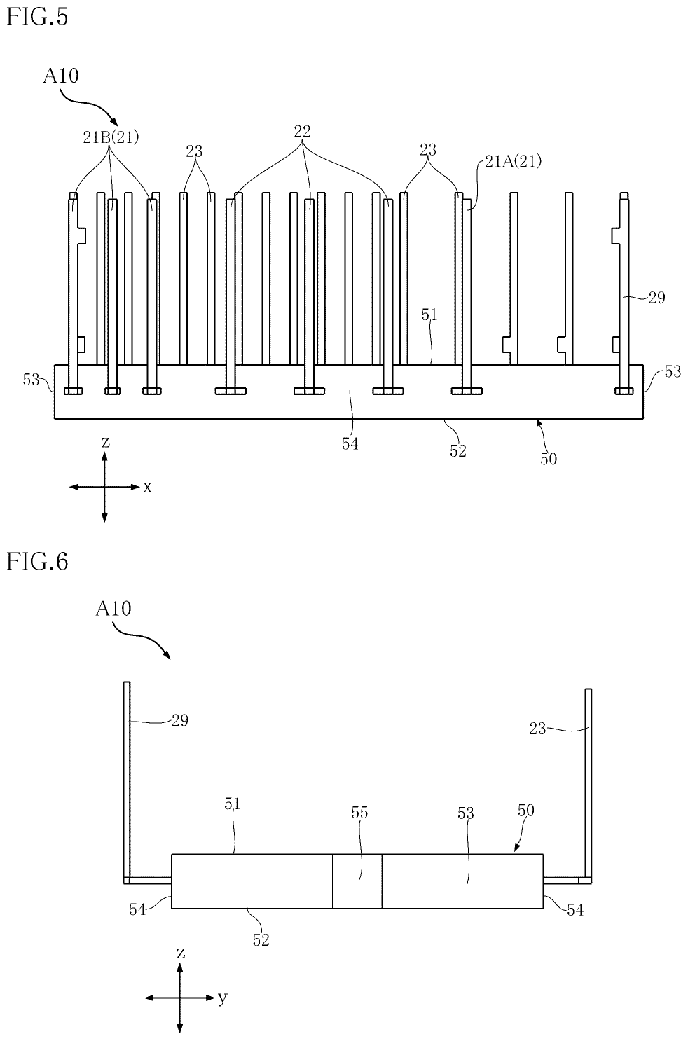

A semiconductor device A10 according to a first embodiment of the present disclosure will be described based on FIGS. 1 to 13. The semiconductor device A10 includes an insulating layer 11, a plurality of conductive layers 12, a heat dissipation layer 13, a plurality of input terminals 21, a plurality of output terminals 22, bonding layers 39, a plurality of first wires 41, a plurality of second wires 42, and a sealing resin 50. The semiconductor device A10 further includes a plurality of control terminals 23, a dummy terminal 29, a plurality of ICs 33, a plurality of diodes 34, a plurality of third wires 43, a plurality of fourth wires 44, a plurality of fifth wires 45, and a plurality of sixth wires 46. In FIG. 3, the sealing resin 50 is shown as transparent for the convenience of understanding. In FIG. 3, the sealing resin 50 is indicated by imaginary lines (two-dot chain lines). In FIG. 3, line VII-VII and line VIII-VIII are shown as single-dot chain lines.

In the description of the semiconductor device A10, the direction that is normal to the obverse surfaces 121 of the conductive layers 12, described later, is referred to as the “first direction z” for the convenience. A direction orthogonal to the first direction z is referred to as the “second direction x”. The direction orthogonal to the first direction z and the second direction x is referred to as the “third direction y”.

The semiconductor device A10 converts the DC power inputted to the input terminals 21 into AC power by using the semiconductor elements 31. The converted AC power is outputted as three different phases (U-phase, V-phase, and W-phase) from the output terminals 22. In the semiconductor device A10, the ICs 33 drive the semiconductor elements 31. Therefore, the semiconductor device A10 is an IPM (Intelligent Power Module). The semiconductor device A10 is used, for example, in a power supply circuit for driving a three-phase AC motor.

As shown in FIGS. 3, 7 and 8, the insulating layer 11 supports the conductive layers 12. The insulating layer 11 is made of a ceramic material containing aluminum nitride (AlN), for example. The insulating layer 11 has a rectangular shape elongated in the second direction x.

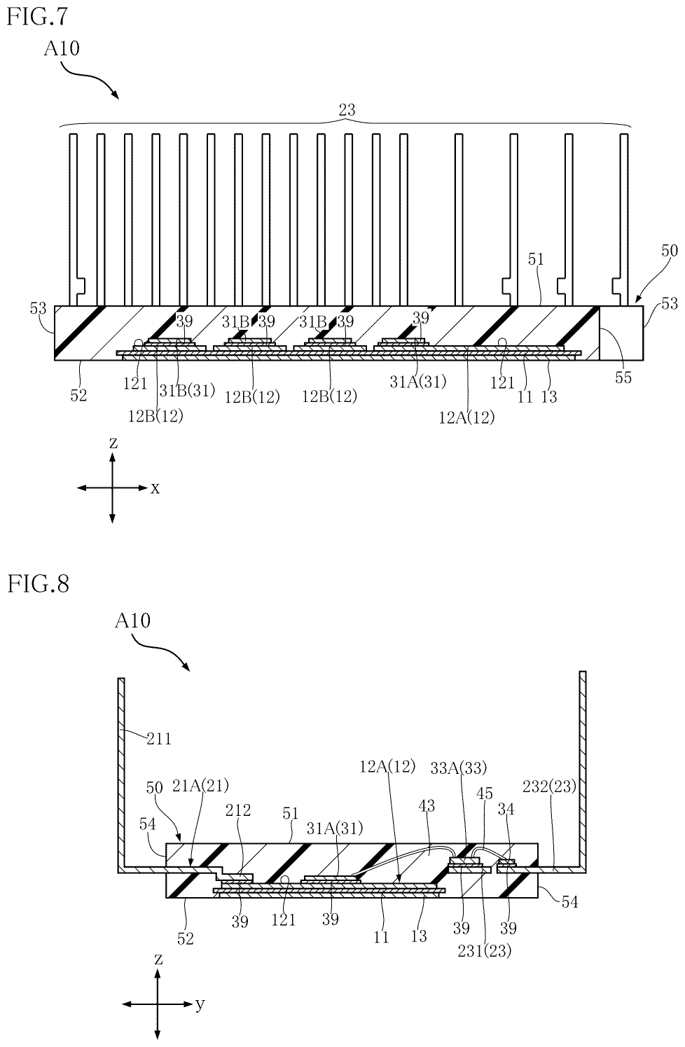

As shown in FIGS. 7 and 8, the conductive layers 12 are bonded to the insulating layer 11. The composition of the conductive layers 12 includes copper (Cu). The conductive layers 12 are surrounded by the outer edge of the insulating layer 11 as viewed in the first direction z. The dimension in the first direction z of each conductive layer 12 is greater than the dimension in the first direction z of the insulating layer 11.

As shown in FIG. 7, each conductive layer 12 has an obverse surface 121. The obverse surface 121 faces away from the insulating layer 11 in the first direction z. As shown in FIG. 3, the plurality of conductive layers 12 include a first conductive layer 12A and a plurality of second conductive layers 12B. The second conductive layers 12B are located on one side in the second direction x of the first conductive layer 12A.

As shown in FIGS. 7 and 8, the heat dissipation layer 13 is located opposite to the conductive layers 12 with respect to the insulating layer 11. The heat dissipation layer 13 is bonded to the insulating layer 11. The composition of the heat dissipation layer 13 includes copper. The heat dissipation layer 13 is surrounded by the outer edge of the insulating layer 11 as viewed in the first direction z. The dimension in the first direction z of the heat dissipation layer 13 is greater than the dimension in the first direction z of the insulating layer 11.

In the semiconductor device A10, the insulating layer 11, the conductive layers 12, and the heat dissipation layer 13 are provided by, for example, a DBC (Direct Bonded Copper) substrate. The conductive layers 12 and the heat dissipation layer 13 are formed by etching the copper foil that forms a part of the DBC substrate.

As shown in FIGS. 3 and 7, each semiconductor element 31 is bonded to the obverse surface 121 of one of the conductive layers 12. The plurality of semiconductor elements 31 include a plurality of first elements 31A and a plurality of second elements 31B. The first elements 31A are bonded to the obverse surface 121 of the first conductive layer 12A among the conductive layers 12. The second elements 31B are bonded to the obverse surfaces 121 of the second conductive layers 12B, respectively, among the conductive layers 12.

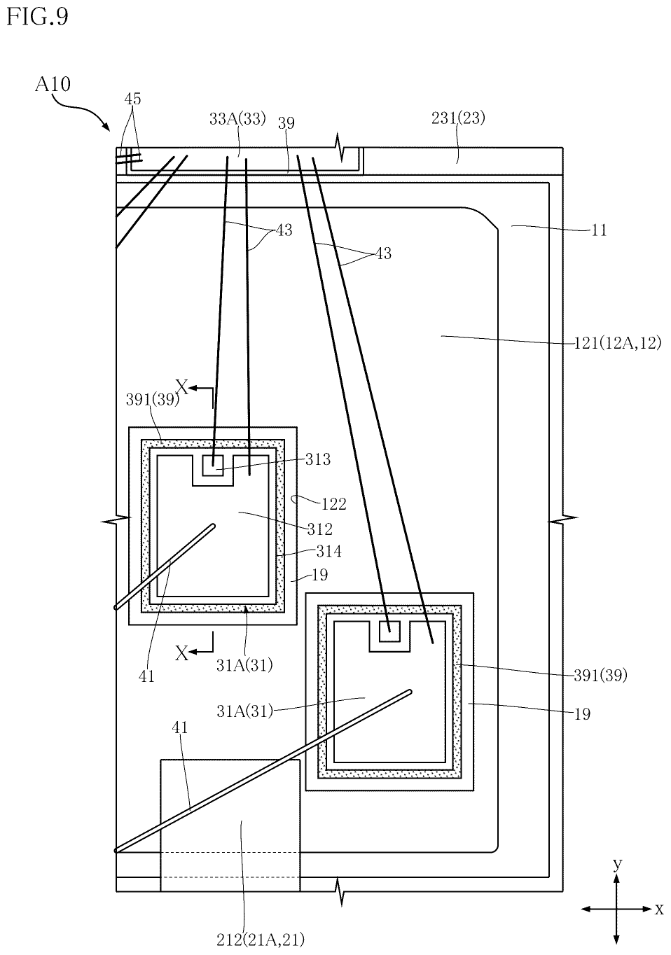

The semiconductor elements 31 are, for example, MOSFETS (Metal-Oxide-Semiconductor Field-Effect Transistor). Alternatively, the semiconductor elements 31 may be switching elements such as IGBTs (Insulated Gate Bipolar Transistor) or diodes. In the semiconductor device A10 described herein, the semiconductor elements 31 are n-channel MOSFETs of a vertical structure type. The semiconductor elements 31 include a compound semiconductor substrate. The composition of the compound semiconductor substrate includes silicon carbide (Sic). As shown in FIG. 9, each of the semiconductor elements 31 includes a first electrode 311, a second electrode 312, and a gate electrode 313.

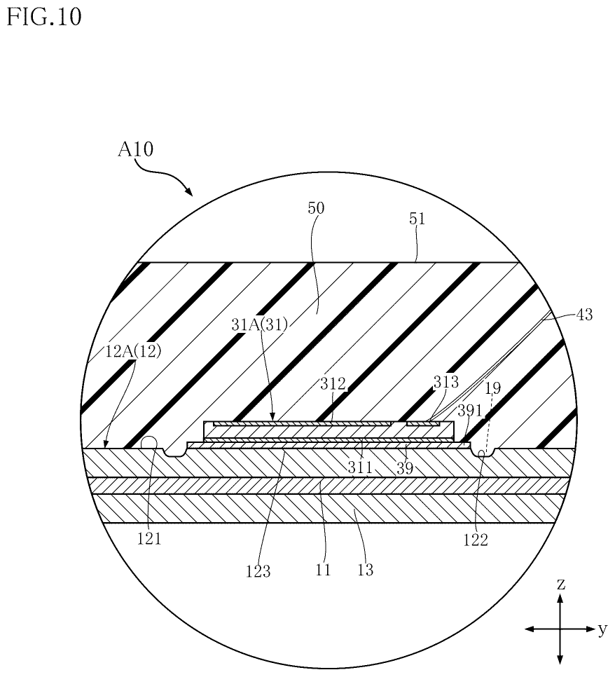

As shown in FIG. 10, the first electrode 311 faces the obverse surface 121 of one of the conductive layers 12. A current corresponding to the electric power before conversion by the semiconductor element 31 flows in the first electrode 311. That is, the first electrode 311 corresponds to the drain electrode of the semiconductor element 31.

As shown in FIG. 9, the second electrode 312 is located opposite to the first electrode 311 in the first direction z. A current corresponding to the electric power after conversion by the semiconductor element 31 flows in the second electrode 312. That is, the second electrode 312 corresponds to the source electrode of the semiconductor element 31. The second electrode 312 includes a plurality of metal plating layers. The second electrode 312 includes a nickel (Ni) plating layer, and a gold (Au) plating layer laminated on the nickel-plating layer. Alternatively, the second electrode 312 may include a nickel plating layer, a palladium (Pd) plating layer laminated on the nickel plating layer, and a gold plating layer laminated on the palladium plating layer.

As shown in FIG. 9, the gate electrode 313 is provided on the same side as the second electrode 312 in the first direction z and is spaced apart from the second electrode 312. A gate voltage for driving the semiconductor element 31 is applied to the gate electrode 313. As shown in FIG. 10, the area of the gate electrode 313 is smaller than the area of the second electrode 312 as viewed in the first direction z.

As shown in FIGS. 7 and 8, each bonding layer 39 bonds the obverse surface 121 of one of the conductive layers 12 and one of the semiconductor elements 31. The first electrode 311 of each of the first elements 31A is conductively bonded to the obverse surface 121 of the first conductive layer 12A via a bonding layer 39. The first electrodes 311 of the second elements 31B are conductively bonded to the obverse surfaces 121 of the second conductive layers 12B, respectively, via the bonding layers 39. The bonding layers 39 are solder.

As shown in FIG. 3, each of the conductive layers 12 is formed with at least one recess 19. The recess 19 is recessed from the obverse surface 121 of the conductive layer 12. The first conductive layer 12A is formed with a plurality of recesses 19. As viewed in the first direction z, the recesses 19 formed in the first conductive layer 12A surround the first elements 31A, respectively. Each of the second conductive layers 12B is formed with a recess 19 located around one of the second elements 31B.

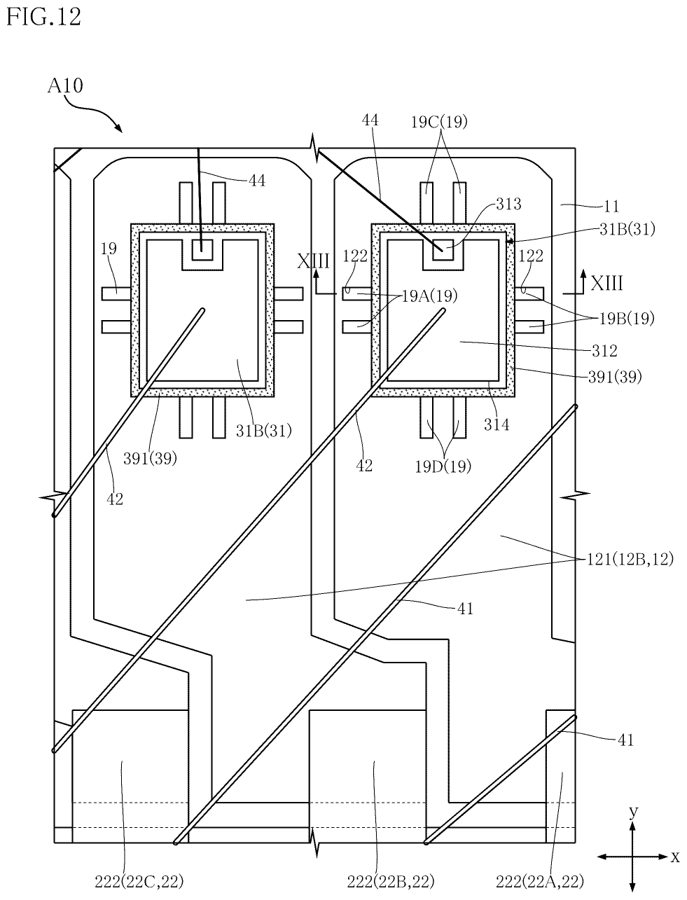

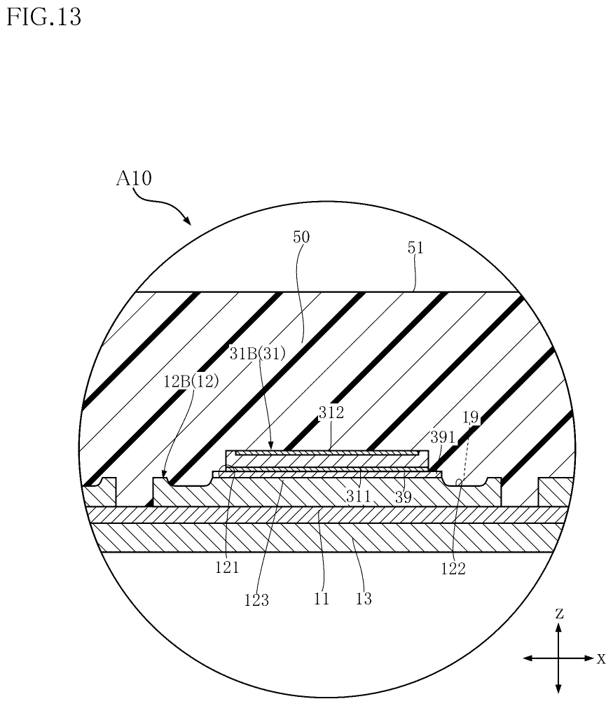

As shown in FIGS. 9 and 12, each bonding layer 39 includes a first portion 391 located between one of the semiconductor elements 31 and the recess 19 as viewed in the first direction z. As shown in FIGS. 10 and 13, the first portion 391 covers the obverse surface 121 of one of the conductive layers 12.

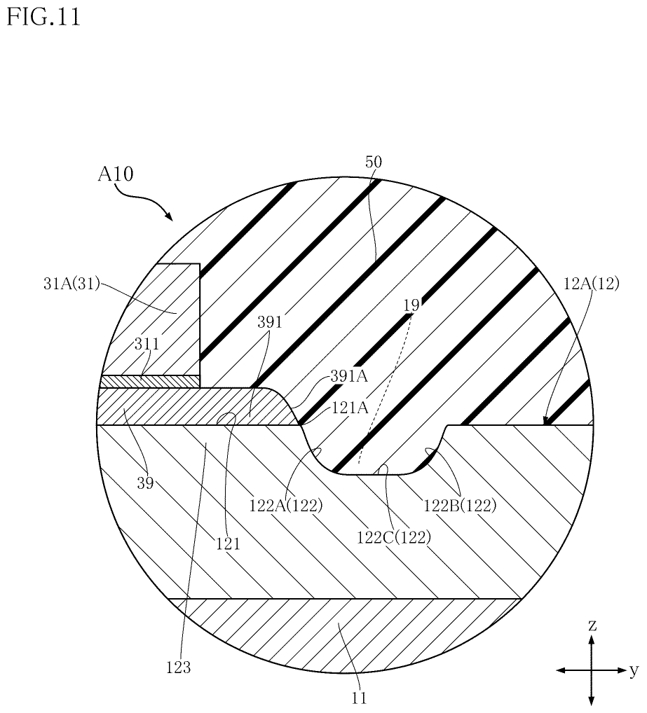

As shown in FIGS. 10 and 13, each of the conductive layers 12 has an inner surface 122. The inner surface 122 is connected to the obverse surface 121 of the conductive layer 12 and defines the recess 19. As shown in FIG. 11, the first portion 391 of the bonding layer 39 reaches the boundary 121A between the inner surface 122 and the obverse surface 121. The end surface 391A of the first portion 391 is inclined with respect to the obverse surface 121. The reason why the end surface 391A is inclined with respect to the obverse surface 121 is that surface tension acts on the molten bonding layer 39 at the boundary 121A when each semiconductor element 31 is bonded to one of the conductive layers 12.

As shown in FIG. 11, each inner surface 122 has a first interior face 122A, a second interior face 122B, and a third interior face 122C. The first interior face 122A and the second interior face 122B face each other in a direction orthogonal to the first direction z. Of these interior faces, the first interior face 122A is located closest to the semiconductor element 31. The first interior face 122A and the second interior face 122B approach each other as they extend from the obverse surface 121 of the conductive layer 12 toward the insulating layer 11 in the first direction z. Each of the first interior face 122A and the second interior face 122B is curved toward the inside of the conductive layer 12. The third interior face 122C is connected to the first interior face 122A and the second interior face 122B. The third interior face 122C faces the same side as the obverse surface 121 in the first direction z.

In the semiconductor device A10, the first conductive layer 12A has a plurality of seat portions 123 as shown in FIGS. 10 and 13. The seat portions 123 are surrounded by the recesses 19, respectively, that are formed in the first conductive layer 12A. Each of the seat portions 123 includes the obverse surface 121 of a first conductive layer 12A. The of elements 31A are first electrodes 311 the first conductively bonded to the obverse surfaces 121 of the seat portions 123, respectively, via the bonding layers 39. The cross-sectional area of each seat portion 123 orthogonal to the first direction z increases from the obverse surface 121 of the first conductive layer 12A toward the insulating layer 11.

As shown in FIG. 12, in the semiconductor device A10, the recess 19 provided in each of the second conductive layers 12B extends in a direction crossing the periphery 314 of the relevant second element 31B as viewed in the first direction z. The recess 19 includes a first recess 19A, a second recess 19B, a third recess 19C, and a fourth recess 19D. The first recess 19A, the second recess 19B, the third recess 19C, and the fourth recess 19D are separated from each other. The first recess 19A and the second recess 19B are located opposite to each other with respect to the second element 31B in the second direction x. The third recess 19C and the fourth recess 19D are located opposite to each other with respect to the second element 31B in third direction y. Each of the first recess 19A, the second recess 19B, the third recess 19C, and the fourth recess 19D includes two separated portions.

The input terminals 21, the output terminals 22, the control terminals 23, and the dummy terminal 29 are made from the same lead frame. The lead frame is made of a material containing copper (Cu) or a copper alloy. Therefore, the composition of the input terminals 21, the output terminals 22, the control terminals 23, and the dummy terminal 29 includes copper.

As shown in FIG. 3, the plurality of input terminals 21 include a first input terminal 21A and a plurality of second input terminals 21B. The second input terminals 21B are located opposite to the first input terminals 21A with respect to the output terminals 22. Each input terminal 21 has an external connection part 211 and an internal connection part 212. The external connection part 211 is exposed to the outside from the sealing resin 50. The internal connection part 212 is connected to the external connection part 211 and covered with the sealing resin 50.

As shown in FIG. 8, the internal connection part 212 of the first input terminal 21A is conductively bonded to the obverse surface 121 of the first conductive layer 12A via the bonding layer 39. The first input terminal 21A corresponds to a P terminal (positive electrode) to which the DC power to be converted is inputted.

The second input terminals 21B are spaced apart from the insulating layer 11. The second input terminals 21B are supported by the sealing resin 50. As shown in FIG. 3, the second input terminals 21B are spaced apart from the conductive layers 12 as viewed in the first direction z. The second input terminals 21B correspond to an N terminal (negative electrode) to which the DC power to be converted is inputted.

As shown in FIG. 3, the output terminals 22 are located between the first input terminal 21A and the second input terminals 21B in the second direction x. The plurality of output terminals 22 include a first output terminal 22A, a second output terminal 22B, and a third output terminal 22C. Each output terminal 22 has an external connection part 221 and an internal connection part 222. The external connection part 221 is exposed to the outside from the sealing resin 50. The internal connection part 222 is connected to the external connection part 221 and covered with the sealing resin 50.

The internal connection parts 222 of the output terminals 22 are conductively bonded to the obverse surfaces 121 of the second conductive layers 12B, respectively, via the bonding layers 39. The three-phase AC power converted by the semiconductor elements 31 is outputted from the output terminals 22.

As shown in FIG. 3, the first wires 41 are individually conductively bonded to the second electrodes 312 of the first elements 31A and the internal connection parts 222 of the output terminals 22. Thus, the second electrodes 312 of the first elements 31A are electrically connected to the second conductive layers 12B, respectively. Also, the first electrode 311 of each of the second elements 31B is electrically connected to the second electrode 312 of one of the first elements 31A. The composition of the first wires 41 includes aluminum (Al). Alternatively, the composition of the first wires 41 may include copper.

As shown in FIG. 3, the second wires 42 are individually conductively bonded to the second electrodes 312 of the second elements 31B and the second input terminals 21B. Thus, the second electrodes 312 of the second elements 31B are electrically connected to the second input terminals 21B, respectively. The composition of the second wires 42 includes aluminum. Alternatively, the composition of the second wires 42 may include copper.

In the semiconductor device A10, the first conductive layer 12A, the first elements 31A, and the first wires 41 constitute a plurality of upper arm circuits. Also, the second conductive layers 12B, the second elements 31B, the second wires 42, and the second input terminals 21B constitute a plurality of lower arm circuits. Therefore, the voltage applied to the gate electrode 313 of each of the first elements 31A differs from the voltage applied to the gate electrode 313 of each of the second elements 31B. Further, because the semiconductor device A10 has a plurality of second input terminals 21B, the grounds of the lower arm circuits are set individually in the semiconductor device A10.

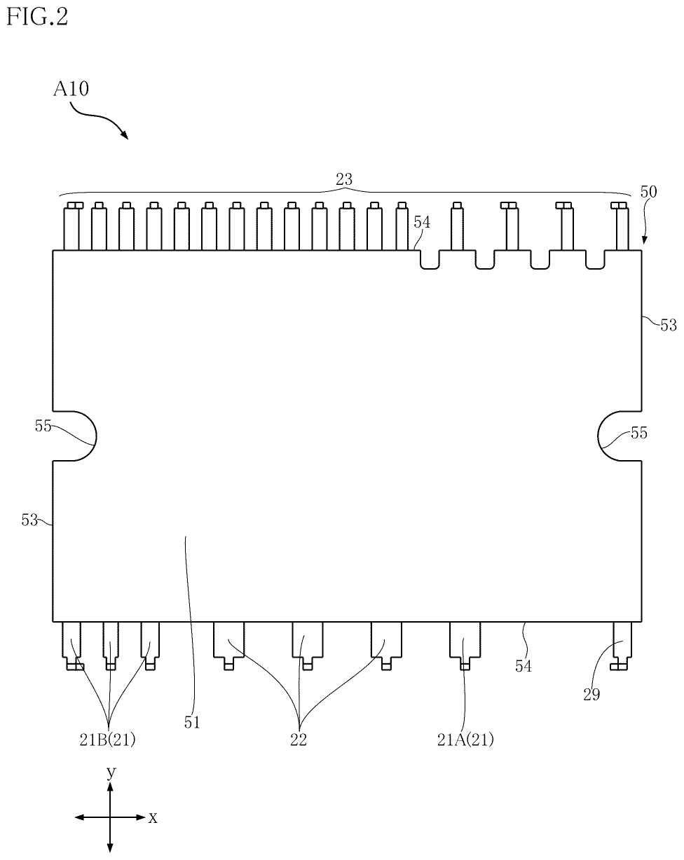

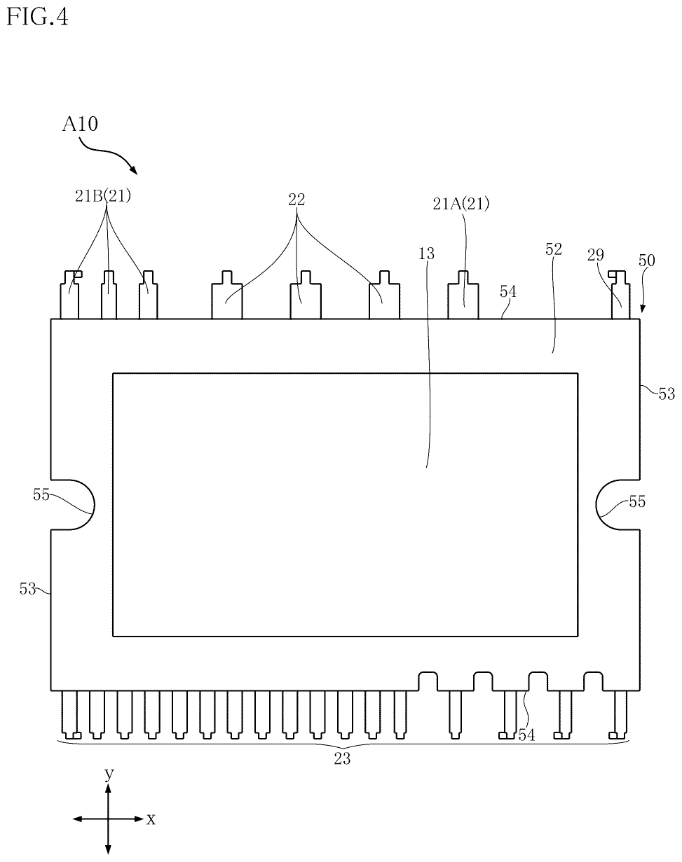

As shown in FIG. 3, the control terminals 23 are located opposite to the input terminals 21 and the output terminals 22 with respect to the conductive layers 12 in the third direction y. As with the second input terminals 21B, the control terminals 23 are spaced apart from the insulating layer 11 and supported by the sealing resin 50. As shown in FIGS. 2 and 4, a part of each control terminal 23 is exposed to the outside from the sealing resin 50.

As shown in FIG. 3, the plurality of control terminals 23 include a pad section 231, a plurality of power supply sections 232, a plurality of first control sections 233, a plurality of second control sections 234, and a dummy section 235. The pad section 231 has a plurality of ICs 33 mounted thereon. The pad section 231 serves as the ground for the ICs 33. The ICs 33 are located opposite to the input terminals 21 and the output terminals 22 with respect to the conductive layers 12 in the third direction y.

As shown in FIG. 3, the plurality of ICs 33 include a first IC 33A and a second IC 33B spaced apart from each other in the second direction x. The power supply sections 232 receive the electric power for producing the gate voltage for driving the first elements 31A. The first control sections 233 receive or output electric signals related to the control of the first IC 33A. The second control sections 234 receive or output electric signals related to the control of the second IC 33B. The dummy section 235 is not electrically connected to the ICs 33.

As shown in FIG. 8, the first IC 33A is bonded to the pad section 231 via a bonding layer 39. As shown in FIG. 3, the first IC 33A is located closer to the first conductive layer 12A than is the second IC 33B. The first IC 33A applies a gate voltage to the gate electrodes 313 of the first elements 31A.

As with the first IC 33A, the second IC 33B is bonded to the pad section 231 via a bonding layer 39. As shown in FIG. 3, the second IC 33B is located closer to the second conductive layers 12B than is the first IC 33A. The second IC 33B applies a gate voltage to the gate electrodes 313 of the second elements 31B.

As shown in FIG. 8, the diodes 34 are conductively bonded to the power supply sections 232 via the bonding layers 39, respectively. The diodes 34 prevent a reverse bias from being applied to the power supply sections 232 when the first elements 31A are driven.

As shown in FIG. 3, the third wires 43 are conductively bonded to the first IC 33A and the second electrodes 312 or the gate electrodes 313 of the first elements 31A. Thus, the first IC 33A applies a gate voltage to the gate electrodes 313 of the first elements 31A. The ground for the gate voltage is set in the first IC 33A. The composition of the third wires 43 includes gold, for example.

As shown in FIG. 3, the fourth wires 44 are conductively bonded to the second IC 33B and the gate electrodes 313 of the second elements 31B. Thus, the second IC 33B applies a gate voltage to the gate electrodes 313 of the second elements 31B. The composition of the fourth wires 44 includes gold, for example.

As shown in FIG. 3, the fifth wires 45 are conductively bonded to the first IC 33A, and the pad section 231, the diodes 34 or the first control sections 233. Thus, the pad section 231, the power supply sections 232, the diodes 34, and the first control sections 233 are electrically connected to the first IC 33A. The composition of the fifth wires 45 includes gold, for example.

As shown in FIG. 3, the sixth wires 46 are connected to the second IC 33B and the pad section 231 or the second control sections 234. Thus, the pad section 231 and the second control sections 234 are electrically connected to the second IC 33B. The composition of the sixth wires 46 includes gold, for example.

As shown in FIG. 3, the dummy terminal 29 is spaced apart from the insulating layer 11 as viewed in the first direction z. The dummy terminal 29 is located opposite to the output terminals 22 with respect to the first input terminal 21A in the second direction x. As shown in FIGS. 2, 4 and 6, a part of the dummy terminal 29 is exposed to the outside from the sealing resin 50.

As shown in FIGS. 7 and 8, the sealing resin 50 covers the conductive layers 12, the semiconductor elements 31, the ICs 33, the internal connection parts 212 of the input terminals 21, and the internal connection parts 222 of the output terminals 22. The sealing resin 50 also covers a part of each control terminal 23 and a part of the dummy terminal 29. The sealing resin 50 is electrically insulating. The sealing resin 50 is made of a material containing black epoxy resin, for example. As shown in FIGS. 10 and 13, a part of the sealing resin 50 is located inside the recesses 19 provided in the conductive layers 12. The sealing resin 50 has a top surface 51, a bottom surface 52, a pair of first side surfaces 53, a pair of second side surfaces 54, and a pair of dented portions 55.

As shown in FIGS. 7 and 8, the top surface 51 faces the same side as the obverse surfaces 121 of the conductive layers 12 in the first direction z. As shown in FIGS. 7 and 8, the bottom surface 52 faces away from the obverse surface 121 in the first direction z. Thus, the top surface 51 and the bottom surface 52 face away from each other in the first direction z. As shown in FIG. 4, the heat dissipation layer 13 is exposed to the outside from the bottom surface 52.

As shown in FIGS. 2, 4, and 5, the paired first side surfaces 53 are spaced apart from each other in the second direction x. The first side surfaces 53 are connected to the top surface 51 and the bottom surface 52.

As shown in FIGS. 2, 4, and 6, the paired second side surfaces 54 are spaced apart from each other in the third direction y. The second side surfaces 54 are connected to the top surface 51 and the bottom surface 52. The external connection part 211 of each input terminal 21, the external connection part 221 of each output terminal 22, and a part of the dummy terminal 29 are exposed to the outside from one of the paired second side surfaces 54. A part of each control terminal 23 is exposed to the outside from the other one of the paired second side surfaces 54.

As shown in FIGS. 2, 4, and 6, the pair of dented portions 55 are dented from the pair of first side surfaces 53 in the second direction x. The dented portions 55 extend from the top surface 51 to the bottom surface 52 in the first direction z. The provision of the paired dented portions 55 increases the creepage distance along the sealing resin 50 from the external connection part 211 of each input terminal 21 to a relevant one of the control terminals 23. Also, the creepage distance along the sealing resin 50 from each second input terminal 21B to a relevant one of the control terminals 23 is also increased. This is favorable for improving the dielectric strength of the semiconductor device A10.

First variation of the first embodiment:

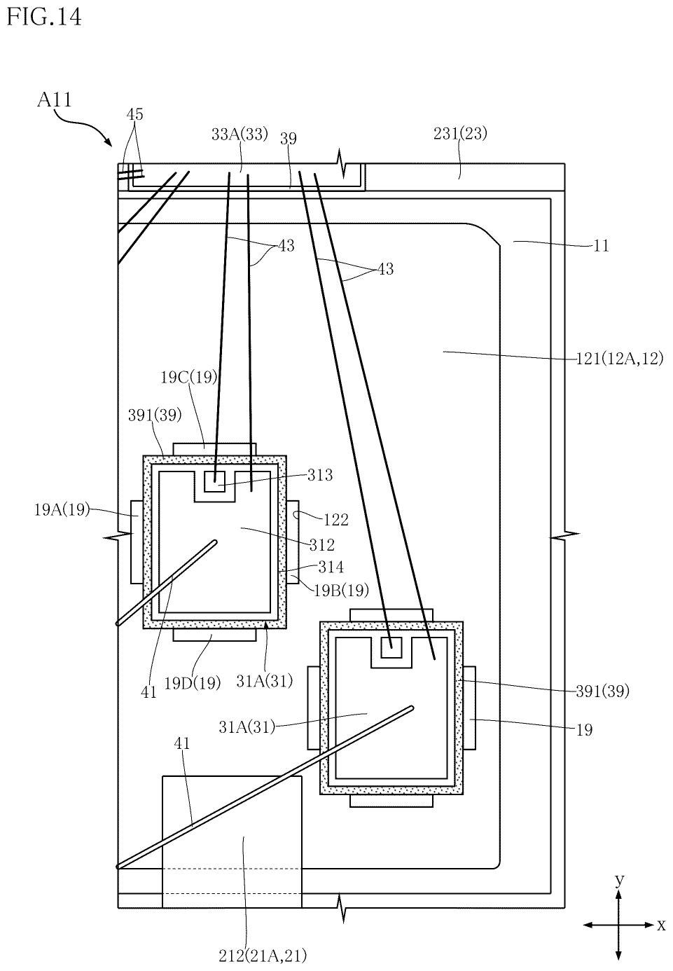

Next, a semiconductor device A11, which is the first variation of the semiconductor device A10, will be described based on FIG. 14. FIG. 14 shows the region corresponding to that shown in FIG. 9.

As shown in FIG. 14, in the semiconductor device A11, each of the recesses 19 provided in the first conductive layer 12A extends along the periphery 314 of one of the first elements 31A as viewed in the first direction z. Each recess 19 includes a first recess 19A, a second recess 19B, a third recess 19C, and a fourth recess 19D. The first recess 19A and the second recess 19B are located opposite to each other with respect to the first element 31A in the second direction x. The third recess 19C and the fourth recess 19D are located opposite to each other with respect to the first element 31A in the third direction y. In the present variation, each of the first recess 19A, the second recess 19B, the third recess 19C, and the fourth recess 19D is a single integral part. However, each of the first recess 19A, the second recess 19B, the third recess 19C, and the fourth recess 19D may include two separated parts as shown in FIG. 12.

Second variation of the first embodiment:

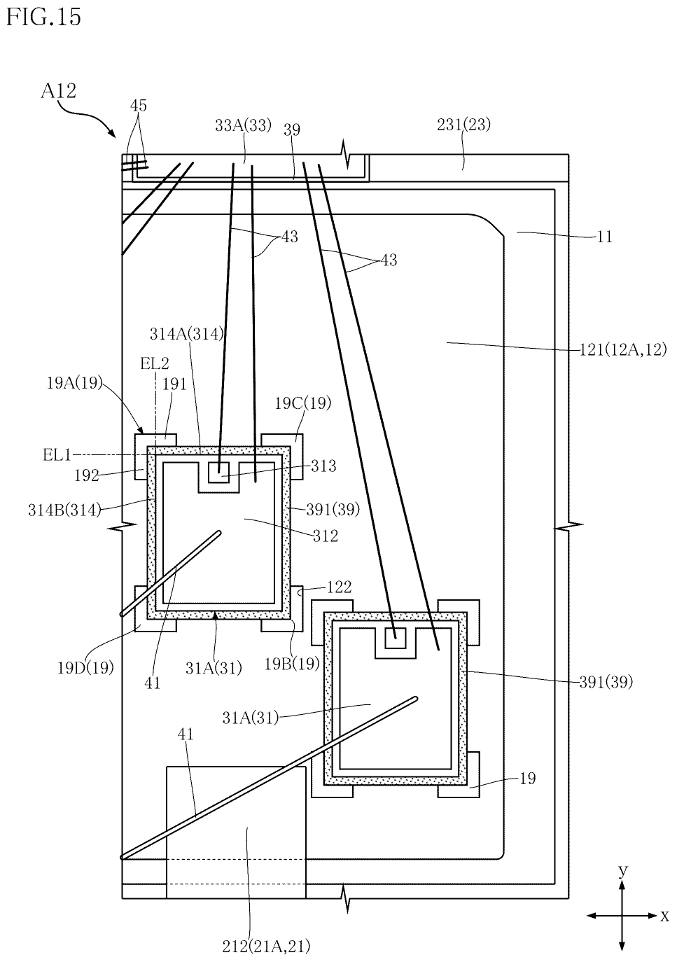

Next, a semiconductor device A12, which is the second variation of the semiconductor device A10, will be described based on FIG. 15. FIG. 15 shows the region corresponding to that shown in FIG. 9.

As shown in FIG. 15, in the semiconductor device A12, each of the recesses 19 provided in the first conductive layer 12A extends along the periphery 314 of one of the first elements 31A as viewed in the first direction z. Each recess 19 includes a first recess 19A, a second recess 19B, a third recess 19C, and a fourth recess 19D. Each of the first recess 19A, the second recess 19B, the third recess 19C, and the fourth recess 19D is located closest to one of the four corners of the first element 31A.

As shown in FIG. 15, the periphery 314 of the first element 31A has a first periphery 314A and a second periphery 314B as viewed in the first direction z. The second periphery 314B extends in a direction different from the first periphery 314A and is connected to the first periphery 314A. Each of the first recess 19A, the second recess 19B, the third recess 19C, and the fourth recess 19D has a first groove 191 and a second groove 192. The first groove 191 extends along the first periphery 314A. The second groove 192 extends along the second periphery 314B and is connected to the first groove 191. As viewed in the first direction z, the first groove 191 and the extension line EL2 of the second periphery 314B cross each other. As viewed in the first direction z, the second groove 192 and the extension line EL1 of the first periphery 314A cross each other.

Third variation of the first embodiment:

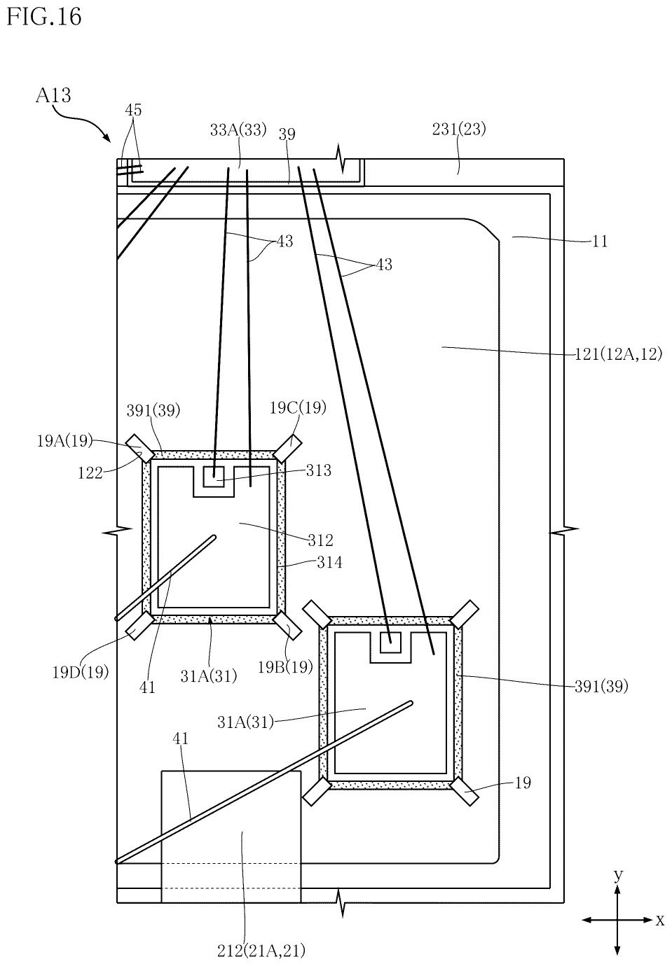

Next, a semiconductor device A13, which is the third variation of the semiconductor device A10, will be described based on FIG. 16. FIG. 16 shows the region corresponding to that shown in FIG. 9.

As shown in FIG. 16, in the semiconductor device A13, each of the recesses 19 provided in the first conductive layer 12A extends in a direction crossing the periphery 314 of one of the first elements 31A as viewed in the first direction z. Each recess 19 includes a first recess 19A, a second recess 19B, a third recess 19C, and a fourth recess 19D. The first recess 19A and the second recess 19B are located opposite to each other with respect to the first element 31A. The third recess 19C and the fourth recess 19D are located opposite to each other with respect to the first element 31A. Each of the first recess 19A, the second recess 19B, the third recess 19C, and the fourth recess 19D is located closest to one of the four corners of the first element 31A.

Fourth variation of the first embodiment:

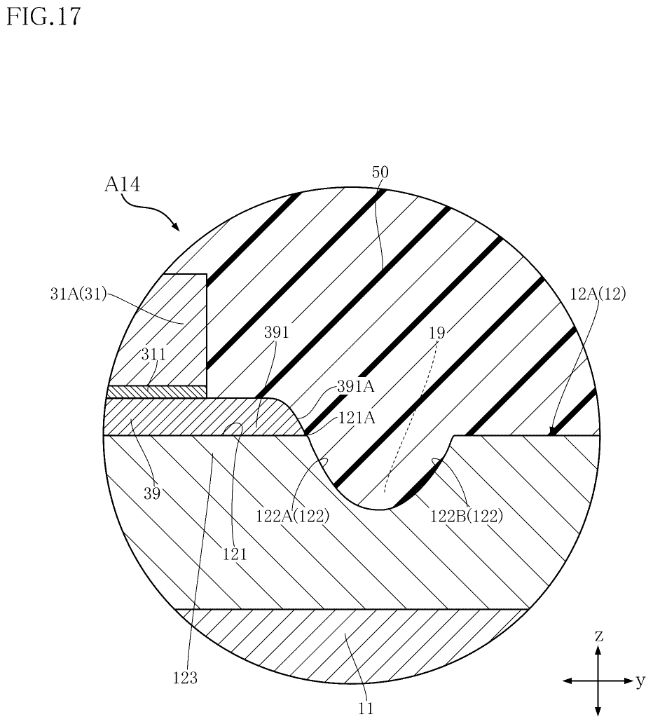

Next, a semiconductor device A14, which is the fourth variation of the semiconductor device A10, will be described based on FIG. 17. FIG. 17 shows the region corresponding to that shown in FIG. 11.

As shown in FIG. 17, in the semiconductor device A14, the inner surface 122 defining a recess 19 in each conductive layer 12 has the first interior face 122A and the second interior face 122B that are connected to each other. In the semiconductor device A14, the inner surface 122 does not include the third interior face 122C.

Next, the effects of the semiconductor device A10 will be described.

The semiconductor device A10 includes the conductive layers 12 bonded to the insulating layer 11, the semiconductor elements 31 bonded to the obverse surfaces 121 of the conductive layers 12, and the bonding layers 39 bonding the obverse surfaces 121 and the semiconductor elements 31. Each conductive layer 12 has a recess 19 that is recessed from the obverse surface 121. Each bonding layer 39 includes a first portion 391 located between the semiconductor element 31 and the recess 19 as viewed in the first direction z. The first portion 391 covers the obverse surface 121. With such a configuration, when the semiconductor element 31 is bonded to the obverse surface 121 via the bonding layer 39, surface tension acts on the molten bonding layer 39 at the boundary 121A between the obverse surface 121 and the recess 19 shown in FIG. 11. This suppresses the spreading of the bonding layer 39 and thereby also suppresses the movement of the semiconductor element 31 due to the spreading of the bonding layer 39. In the semiconductor device A10 having such a configuration, the accuracy in the bond positions of the semiconductor elements 31 to the conductor layer 12 can be improved.

The above effects can also be obtained by providing the conductive layer 12 with a slit that penetrates the conductive layer 12 in the first direction z near the bond position of the semiconductor element 31. However, the semiconductor device A10 employs the recess 19 rather than such a slit. This suppresses the volume reduction of the conductive layer 12, and hence suppresses a decrease in the thermal conduction of the conductive layer 12 in the direction orthogonal to the first direction z.

The conductive layer 12 includes the inner surface 122 connected to the obverse surface 121 and defining the recess 19. The inner surface 122 has the first interior face 122A and the second interior face 122B that face each other in a direction orthogonal to the first direction z. The first interior face 122A and the second interior face 122B approach each other as they extend from the obverse surface 121 toward the insulating layer 11. With such a configuration, the size of the recess 19 can be set as small as possible. This further suppresses the volume reduction of the conductive layer 12.

The recess 19 surrounds the semiconductor element 31 as viewed in the first direction z. With such a configuration, in bonding the semiconductor element 31 to the obverse surface 121 of the conductive layer 12 via a bonding layer 39, the movement of the semiconductor element 31 in a direction orthogonal to the first direction z is suppressed, and the rotation of the semiconductor element 31 about the first direction z is also suppressed.

In the above case, the conductive layer 12 has the seat portion 123 surrounded by the recess 19. The cross-sectional area of the seat portion 123 orthogonal to the first direction z increases from the obverse surface 121 of the first conductive layer 12A toward the insulating layer 11. Such a configuration allows the heat conducted from the semiconductor element 31 to the seat portion 123 to be conducted over a wider area. This improves the heat dissipation of the conductive layer 12.

As viewed in the first direction z, the periphery 314 of the semiconductor element 31 has a first periphery 314A, and a second periphery 314B extending in a direction different from the first periphery 314A and connected to the first periphery 314A. The recess 19 has a first groove 191 extending along the first periphery 314A, and a second groove 192 extending along the second periphery 314B and connected to the first groove 191. As viewed in the first direction z, the first groove 191 and the extension line EL2 of the second periphery 314B cross each other, while the second groove 192 and the extension line EL1 of the first periphery 314A cross each other (see FIG. 15). Such a configuration suppresses the rotation of the semiconductor element 31 in either sense about the first direction z when the semiconductor element is being bonded to the the obverse surface 121 of the conductive layer 12 via a bonding layer 39.

The recess 19 includes the first recess 19A and the second recess 19B separated from the first recess 19A. The first recess 19A and the second recess 19B are located opposite to each other with respect to the semiconductor element 31. Such a configuration also suppresses the spreading of the bonding layer 39 when the semiconductor element 31 is bonded to the obverse surface 121 of the conductive layer 12 via a bonding layer 39.

The semiconductor device A10 further includes the sealing resin 50 covering the semiconductor elements 31. A part of the sealing resin 50 is located inside the recesses 19. With such a configuration, the sealing resin 50 exerts an anchoring effect on the conductive layer 12. This suppresses the separation at the interface between the obverse surface 121 of the conductive layer 12 and the sealing resin 50.

The sealing resin 50 has a bottom surface 52 facing away from the obverse surface 121 of the conductive layer 12 in the first direction z. The heat dissipation layer 13 is exposed from the bottom surface 52. Such a configuration improves the heat dissipation of the semiconductor device A10.

### Second Embodiment

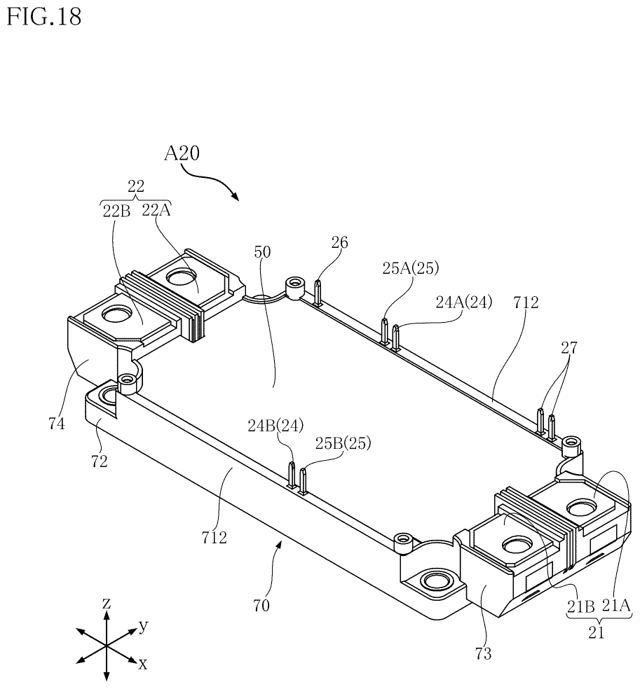

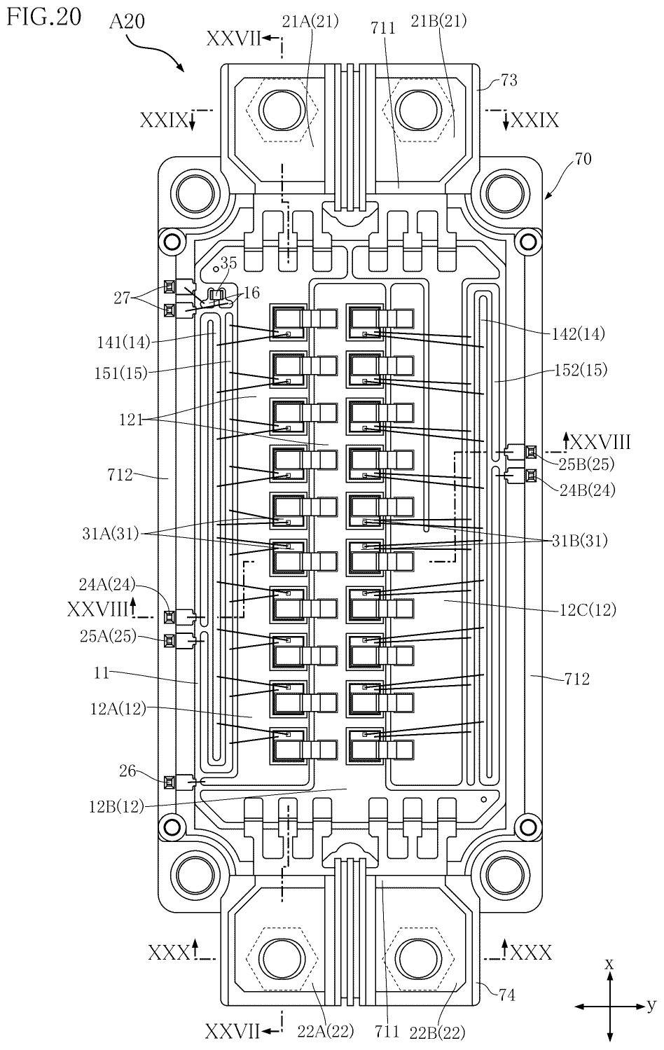

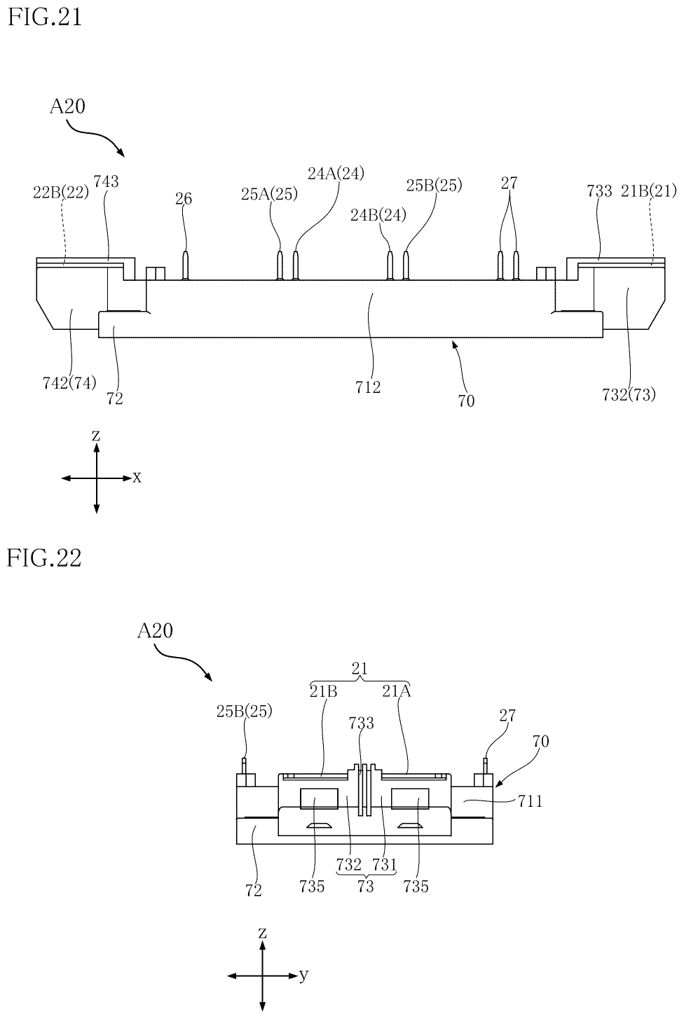

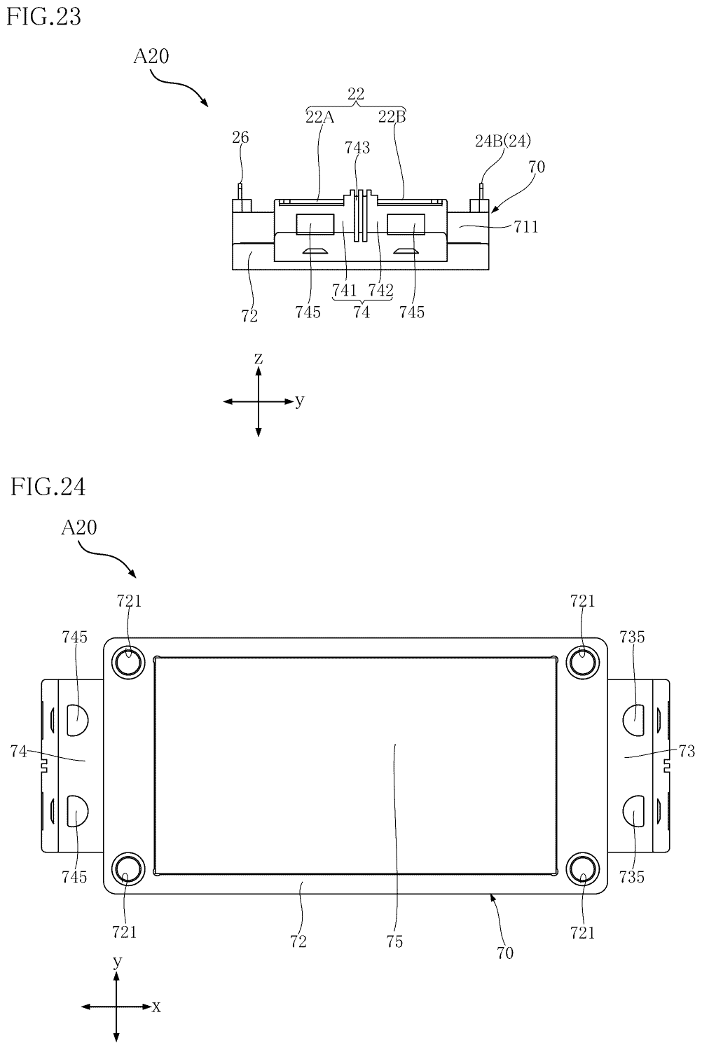

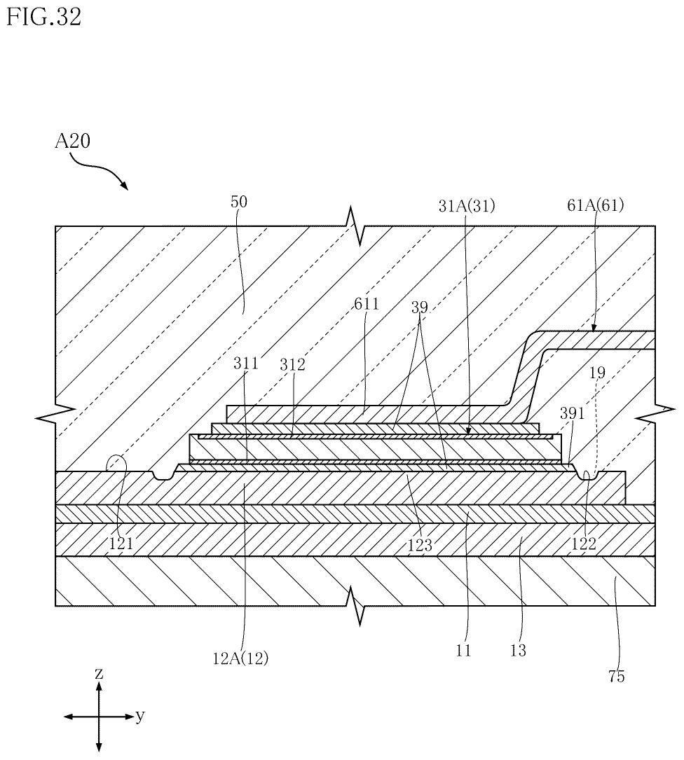

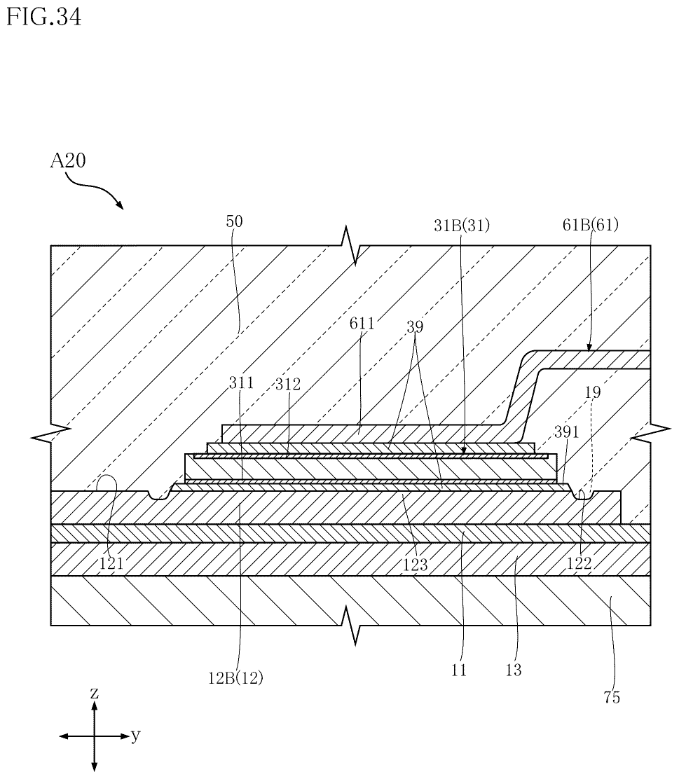

A semiconductor device A20 according to a second embodiment of the present disclosure will be described based on FIGS. 18 to 34. In these figures, the elements that are identical or similar to those of the semiconductor device A10 described above are denoted by the same reference signs, and the descriptions thereof are omitted. In FIGS. 20, 25 and 26, the illustration of the sealing resin 50 is omitted for the convenience of understanding. In FIG. 20, line XXVII-XXVII and line XXVIII-XXVIII are shown as single-dot chain lines.

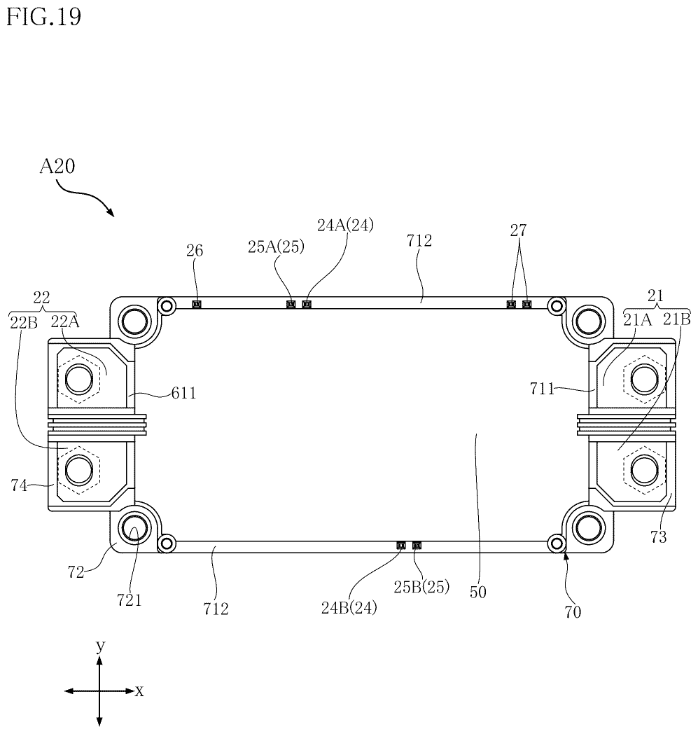

The semiconductor device A20 includes an insulating layer 11, a plurality of conductive layers 12, a heat dissipation layer 13, a plurality of input terminals 21, an output terminal 22, a plurality of semiconductor elements 31, and a sealing resin 50. The semiconductor device A20 also includes a plurality of gate wirings 14, a plurality of detection wirings 15, a plurality of gate terminals 24, a plurality of detection terminals 25, and a case 70. The semiconductor device A20 is a power module. The semiconductor device A20 is used in inverters for electrical appliances or hybrid vehicles. As shown in FIGS. 18 and 19, the semiconductor device A20 is rectangular (or generally rectangular) as viewed in the first direction z. The second direction x corresponds to the longitudinal direction of the semiconductor device A20.

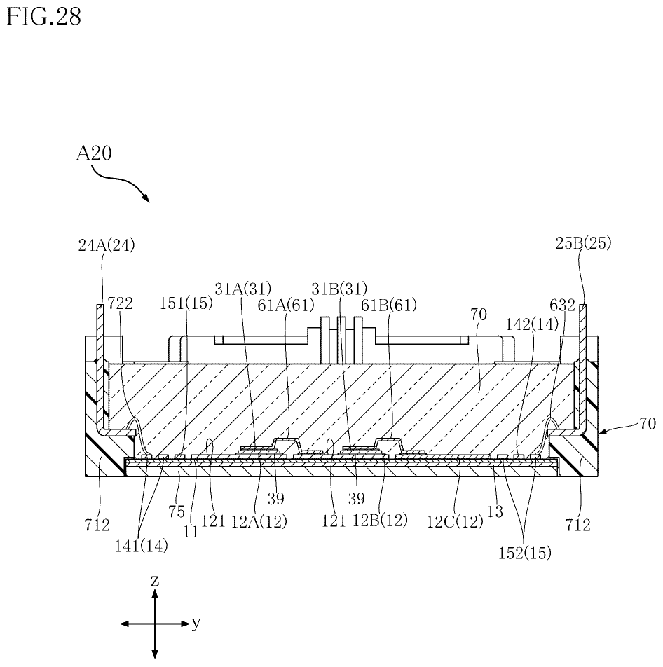

As shown in FIGS. 27 and 28, the insulating layer 11 is bonded to a heat dissipation member 75 via the heat dissipation layer 13. As shown in FIG. 24, a part of the heat dissipation member 75 is exposed to the outside of the semiconductor device A20. The heat dissipation member 75 is, for example, a flat metal plate. The composition of the metal plate includes copper. The surface of the heat dissipation member 75 may be plated with nickel. The dimension of the heat dissipation member 75 in the first direction z is greater than the dimension of the heat dissipation layer 13 in the first direction z.

As shown in FIG. 20, the plurality of conductive layers 12 include a first conductive layer 12A, a second conductive layer 12B, and a third conductive layer 12C. Each of the first conductive layer 12A, the second conductive layer 12B, and the third conductive layer 12C extends in the second direction x. The second conductive layer 12B is locate on one side of the first conductive layer 12A in the third direction y. The third conductive layer 12C is located opposite to the first conductive layer 12A with respect to the second conductive layer 12B in the third direction y.

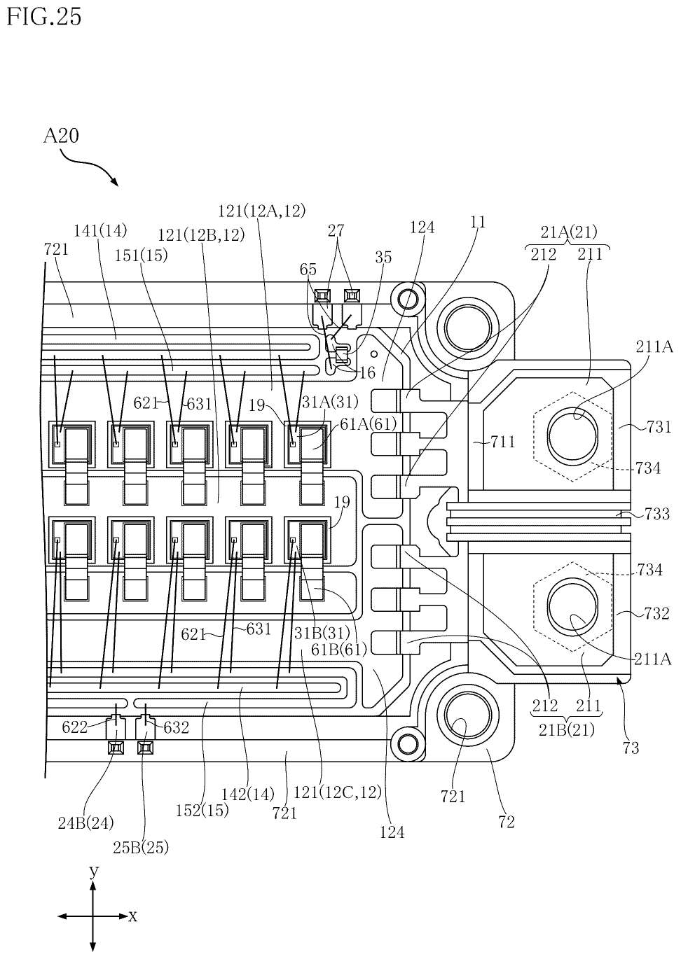

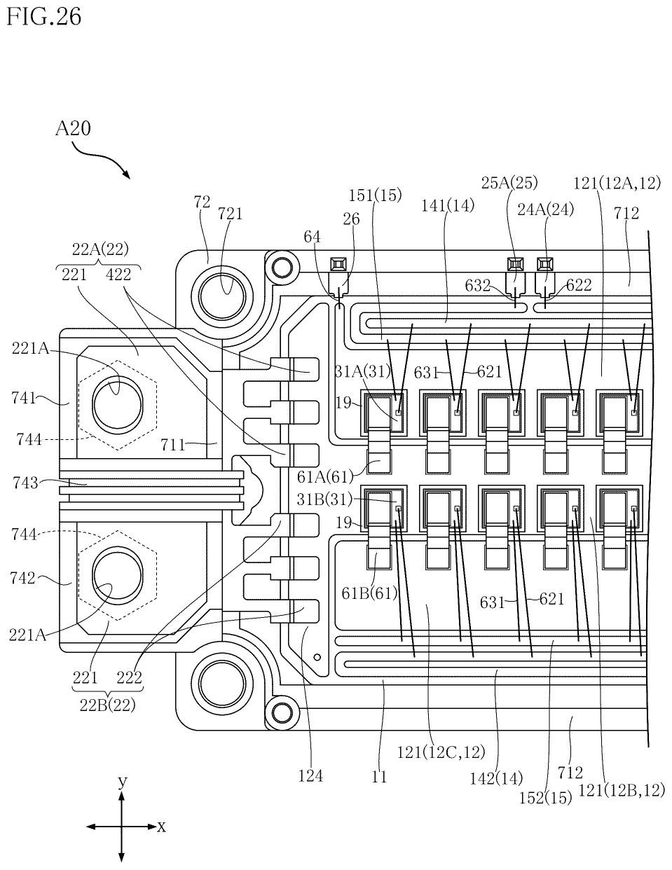

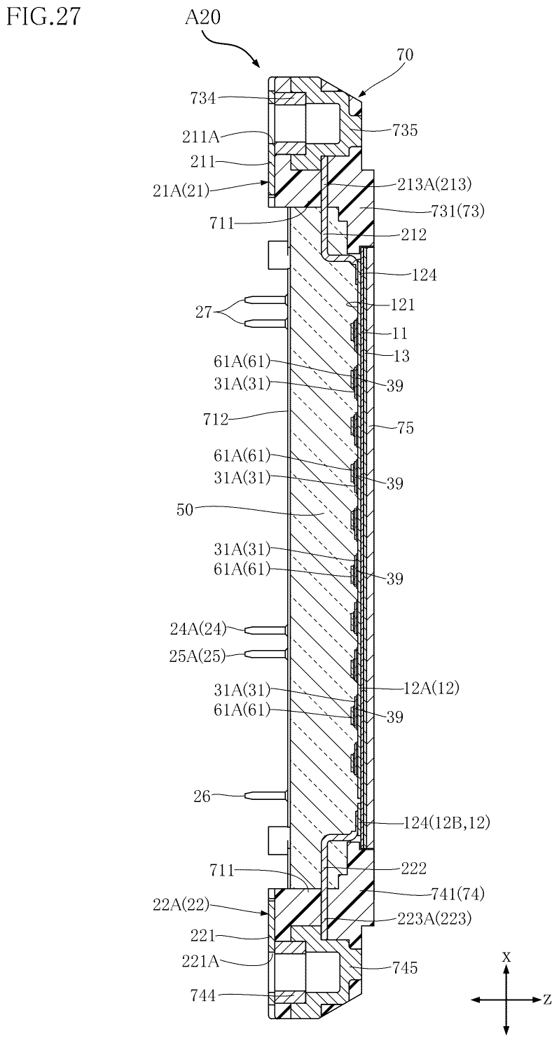

As shown in FIGS. 25 and 26, each of the first conductive layer 12A and the second conductive layer 12B is formed with a plurality of recesses 19. As viewed in the first direction z, the recesses 19 formed in the first conductive layer 12A surround the first elements 31A, respectively. As viewed in the first direction z, the recesses 19 formed in the second conductive layer 12B surround the second elements 31B, respectively.

As shown in FIG. 20, the gate wirings 14 are bonded to the insulating layer 11 to be located on the same side as the conductive layers 12 in the first direction z. The plurality of gate wirings 14 include a first gate wiring 141 and a second gate wiring 142. The first gate wiring 141 is located opposite to the second conductive layer 12B across the first conductive layer 12A in the third direction y. The first gate wiring 141 extends in the second direction x. The first gate wiring 141 includes two portions spaced apart from each other in the third direction y. The two portions of the first gate wiring 141 are connected to each other at respective one ends located closest to the input terminals 21. The second gate wiring 142 is located opposite to the second conductive layer 12B across the third conductive layer 12C in the third direction y. The second gate wiring 142 extends in the second direction x. The second gate wiring 142 includes two portions spaced apart from each other in the third direction y. The two portions of the second gate wiring 142 are connected to each other at respective one ends located closest to the output terminal 22.

As shown in FIG. 20, the detection wirings 15 are bonded to the insulating layer 11 to be located on the same side as the conductive layers 12 in the first direction z. The plurality of detection wirings 15 include a first detection wiring 151 and a second detection wiring 152. The first detection wiring 151 is located next to the first gate wiring 141 in the third direction y. The first detection wiring 151 extends in the second direction x. The first detection wiring 151 includes two portions spaced apart from each other in the third direction y. The two portions of the first detection wiring 151 are connected to each other at respective one ends located closest to the output terminal 22. The second detection wiring 152 is located next to the second gate wiring 142 in the third direction y. The second detection wiring 152 extends in the second direction x. The second detection wiring 152 includes two portions spaced apart from each other in the third direction y. The two portions of the second detection wiring 152 are connected to each other at respective one ends located closest to the input terminals 21.

As shown in FIG. 25, the semiconductor device A20 further includes a pair of pads 16. The pads 16 are bonded to the insulating layer 11 to be located on the same side as the conductive layers 12 in the first direction z. The pads 16 are next to each other in the second direction x. The pads 16 are located at a corner of the insulating layer 11. The pads 16 are close to the first conductive layer 12A.

As shown in FIGS. 19 and 20, the input terminals 21 are part of the external connection terminals provided in the semiconductor device A20. The input terminals 21 are connected to a DC power supply disposed outside the semiconductor device A20. The input terminals 21 are supported on the case 70. The input terminals 21 are formed from a metal plate. The metal plate contains copper, for example.

As shown in FIG. 25, the plurality of input terminals 21 include a first input terminal 21A and a second input terminal 21B. The first input terminal 21A is a positive electrode (P terminal). The first input terminal 21A is bonded to a bond portion 124 of the first conductive layer 12A. Thus, the first input terminal 21A is electrically connected to the first conductive layer 12A. The second input terminal 21B is a negative electrode (N terminal). The second input terminal 21B is bonded to a bond portion 124 of the third conductive layer 12C. Thus, the second input terminal 21B is electrically connected to the third conductive layer 12C. The first input terminal 21A and the second input terminal 21B are next to each other in the third direction y.

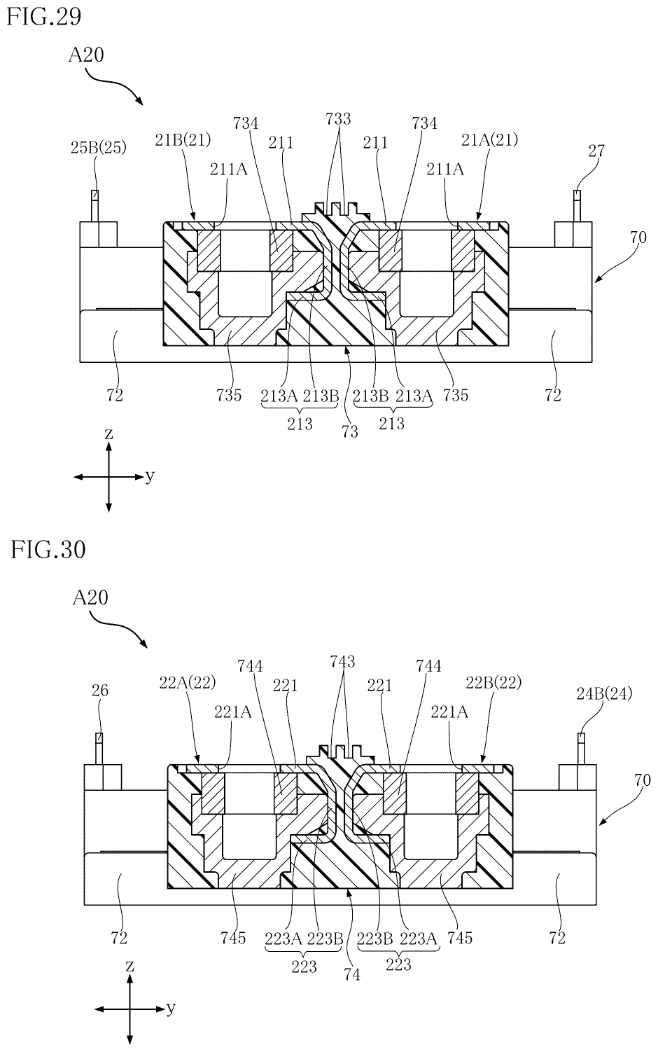

As shown in FIGS. 25 and 29, each of the first input terminal 21A and the second input terminal 21B has an external connection part 211, an internal connection part 212, and an intermediate part 213.

The external connection part 211 is exposed from the semiconductor device A20 and has the shape of a flat plate orthogonal to the first direction z. A DC power supply cable or the like is connected to the external connection part 211. The external connection part 211 is supported on the case 70. The external connection part 211 has a connection hole 211A penetrating in the first direction z. A fastening member, such as a bolt, is inserted into the connection hole 211A. The surface of the external connection part 211 may be plated with nickel (Ni).

The internal connection part 212 of the first input terminal 21A is conductively bonded to a bond portion 124 of the first conductive layer 12A. The internal connection part 212 of the second input terminal 21B is conductively bonded to a bond portion 124 of the third conductive layer 12C. Each internal connection part 212 has a plurality of teeth arranged along the third direction y. The teeth are bent in the first direction z. Thus, each of the teeth has the shape of a hook as viewed in the third direction y. The teeth are conductively bonded to the bond portion 124 of the first conductive layer 12A or the third conductive layer 12C by ultrasonic vibrations.

The intermediate part 213 connects the external connection part 211 and the internal connection part 212 to each other. The intermediate part 213 is L-shaped in cross section orthogonal to the second direction X. The intermediate part 213 has a base portion 213A and a standing portion 213B. The base portion 213A is along the second direction x and the third direction y. One end of the base portion 213A in the second direction x is connected to the internal connection part 212. The standing portion 213B stands from the base portion 213A in the first direction z. One end of the standing portion 213B in the first direction z is connected to the external connection part 211.

As shown in FIGS. 19 and 20, the output terminal 22 is part of the external connection terminals provided in the semiconductor device A20. The output terminal 22 is connected to a power supply target (e.g., a motor) disposed outside the semiconductor device A20. The output terminal 22 is supported on the case 70 and located opposite to the input terminals 21 with respect to the insulating layer 11 in the second direction x. The output terminal 22 is formed from a metal plate. The metal plate contains copper, for example.

In the semiconductor device A20, the output terminal 22 is separated into two, i.e., the first output terminal 22A and the second output terminal 22B. Alternatively, the output terminal 22 may be a single member in which the first output terminal 22A and the second output terminal 22B are combined. The first output terminal 22A and the second output terminal 22B are conductively bonded to the bond portion 124 of the second conductive layer 12B. Thus, the output terminal 22 is electrically connected to the second conductive layer 12B. The first output terminal 22A and the second output terminal 22B are next to each other in the third direction y.

As shown in FIGS. 26 and 30, each of the first output terminal 22A and the second output terminal 22B has an external connection part 221, an internal connection part 222, and an intermediate part 223.

The external connection part 221 is exposed from the semiconductor device A20 and has the shape of a flat plate orthogonal to the first direction z. A cable or the like electrically connected to the power supply targe is bonded to the external connection part 221. The external connection part 221 is supported on the case 70. The external connection part 221 has a connection hole 221A penetrating in the first direction z. A fastening member, such as a bolt, is inserted into the connection hole 221A. The surface of the external connection part 211 may be plated with nickel.

The internal connection part 222 is conductively bonded to a bond portion 124 of the second conductive layer 12B. The internal connection part 222 has a plurality of teeth arranged along the third direction y. The teeth are bent in the first direction z. Thus, each of the teeth has the shape of a hook as viewed in the third direction y. The teeth are conductively bonded to the bond portion 124 of the second conductive layer 12B by ultrasonic vibrations.

The intermediate part 223 connects the external connection part 221 and the internal connection part 222 to each other. The intermediate part 233 is L-shaped in cross section orthogonal to the second direction x. The intermediate part 223 has a base portion 223A and a standing portion 223B. The base portion 223A is along the second direction x and the third direction y. One end of the base portion 223A in the second direction x is connected to the internal connection part 222. The standing portion 223B stands from the base portion 223A in the first direction z. One end of the standing portion 223B in the first direction z is connected to the external connection part 221.

The semiconductor device A20 converts the DC power inputted to the input terminals 21 into AC power by using the semiconductor elements 31. The converted AC power is outputted from the output terminal 22. The AC power is supplied to a power supply target, such as a motor.

As shown in FIGS. 19 to 21, the gate terminals 24 are part of the external connection terminals provided in the semiconductor device A20. The gate terminals 24 are electrically connected to the gate wirings 14. The gate terminals 24 are connected to a drive circuit (e.g., a gate driver) for the semiconductor device A20 which is disposed outside. The gate terminals 24 are supported on the case 70. The gate terminals 24 are formed from metal rods. The metal rods contain copper, for example. The surfaces of the gate terminals 24 may be plated with tin (Sn) or plated with nickel and tin. As shown in FIG. 28, the gate terminals 24 are L-shaped in cross section orthogonal to the second direction x. Each of the gate terminals 24 partially protrudes from the case 70 toward the side which the obverse surfaces 121 of the conductive layers 12 face in the first direction z.

The plurality of gate terminals 24 include a first gate terminal 24A and a second gate terminal 24B. As shown in FIG. 26, the first gate terminal 24A is located close to the first gate wiring 141 in the third direction y. As shown in FIG. 25, the second gate terminal 24B is located opposite to the first gate terminal 24A with respect to the insulating layer 11 in the third direction y. The second gate terminal 24B is located close to the second gate wiring 142.

As shown in FIGS. 19 to 21, the detection terminals 25 are part of the external connection terminals provided in the semiconductor device A20. The detection terminals 25 are electrically connected to the detection wirings 15. The detection terminals 25 are connected to a control circuit for the semiconductor device A20 which is disposed outside. The detection terminals 25 are supported on the case 70. The detection terminals 25 are formed from metal rods. The metal rods contain copper, for example. The surfaces of the detection terminals 25 may be plated with tin or plated with nickel and tin. As shown in FIG. 28, the detection terminals 25 are L-shaped in cross section orthogonal to the second direction x. Each of the detection terminals 25 partially protrudes from the case 70 toward the side which the obverse surfaces 121 of the conductive layers 12 face in the first direction z.

The plurality of detection terminals 25 include a first detection terminal 25A and a second detection terminal 25B. As shown in FIG. 26, the first detection terminal 25A is located next to the first gate terminal 24A in the second direction x. As shown in FIG. 25, the second detection terminal 25B is located next to the second gate terminal 24B in the second direction x.

As shown in FIGS. 19 to 21 and 26, the semiconductor device A20 further includes an input current detection terminal 26. The input current detection terminal 26 is part of the external connection terminals provided in the semiconductor device A20. The input current detection terminal 26 is connected to a control circuit for the semiconductor device A20 which is disposed outside. The input current detection terminal 26 is supported on the case 70. The input current detection terminal 26 is formed from a metal rod. The metal rod contains copper, for example. The surface of the input current detection terminal 26 may be plated with tin or plated with nickel and tin. The shape of the input current detection terminal 26 is the same as that of the gate terminals 24 shown in FIG. 28. As with the gate terminals 24 shown in FIG. 28, the input current detection terminal 26 partially protrudes from the case 70 toward the side which the obverse surfaces 121 of the conductive layers 12 face in the first direction z. In the third direction y, the position of the input current detection terminal 26 is the same as the position of the first gate terminal 24A. The input current detection terminal 26 is spaced apart from first gate terminal 24A toward the side on which the output terminal 22 is located in the second direction x.

As shown in FIG. 26, the semiconductor device A20 further includes an input current detection wire 64. The input current detection wire 64 is conductively bonded to the input current detection terminal 26 and the first conductive layer 12A. Thus, the input current detection terminal 26 is electrically connected to the first conductive layer 12A. The input current detection wire 64 is made of aluminum, for example.

As shown in FIGS. 19 to 21 and 25, the semiconductor device A20 further includes a pair of thermistor terminals 27. The thermistor terminals 27 are part of the external connection terminals provided in the semiconductor device A20. The thermistor terminals 27 are connected to the control circuit for the semiconductor device A20 which is disposed outside. The thermistor terminals 27 are supported on the case 70. The thermistor terminals 27 are formed from metal rods. The metal rods contain copper, for example. The surfaces of the thermistor terminals 27 may be plated with tin or plated with nickel and tin. The shape of the thermistor terminals 27 is the same as that of the gate terminals 24 shown in FIG. 28. As with the gate terminals 24 shown in FIG. 28, the thermistor terminals 27 partially protrude from the case 70 toward the side which the obverse surfaces 121 of the conductive layers 12 face in the first direction z. In the third direction y, the position of the thermistor terminals 27 is the same as the position of the first gate terminal 24A. The thermistor terminals 27 are spaced apart from the first gate terminal 24A toward the side on which the input terminals 21 are located in the second direction x. The thermistor terminals 27 are next to each other in the second direction x.

As shown in FIG. 25, the semiconductor device A20 further includes a pair of thermistor wires 65. The pair of thermistor wires 65 are individually conductively bonded to the pair of thermistor terminals 27 and the pair of pads 16. Thus, the input current detection terminals 26 are electrically connected to the pads 16. The thermistor wires 65 are made of aluminum, for example.

As shown in FIGS. 20 and 25, the semiconductor device A20 further includes a thermistor 35. The thermistor 35 is conductively bonded to the pair of pads 16. In the semiconductor device A20, the thermistor 35 is an NTC (Negative Temperature Coefficient) thermistor. The NTC thermistor has the characteristic that its resistance gradually decreases as the temperature rises. The thermistor 35 is used as a temperature detection sensor of the semiconductor device A20. The thermistor 35 is electrically connected to the pair of thermistor terminals 27 via the pair of pads 16 and the pair of thermistor wires 65.

As shown in FIGS. 25 and 26, the semiconductor device A20 further includes a plurality of conductive members 61, a plurality of first gate wires 621, and a plurality of first detection wires 631. These are individually conductively bonded to the semiconductor elements 31. The conductive members 61 are metal clips. The composition of the conductive members 61 includes copper. Alternatively, each of the conductive members 61 may be constituted of a plurality of wires. The first gate wires 621 and the first detection wires 631 are made of aluminum, for example.

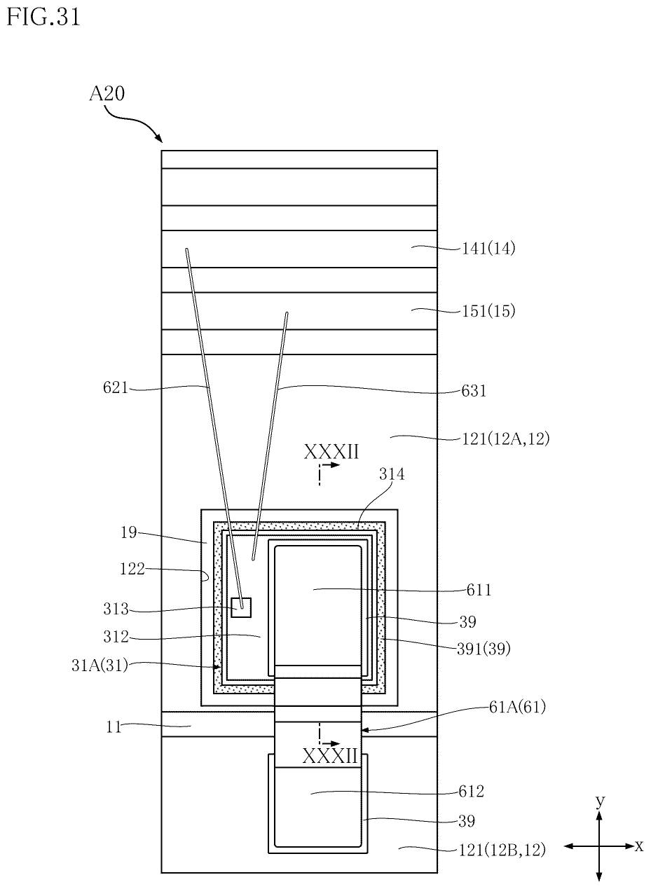

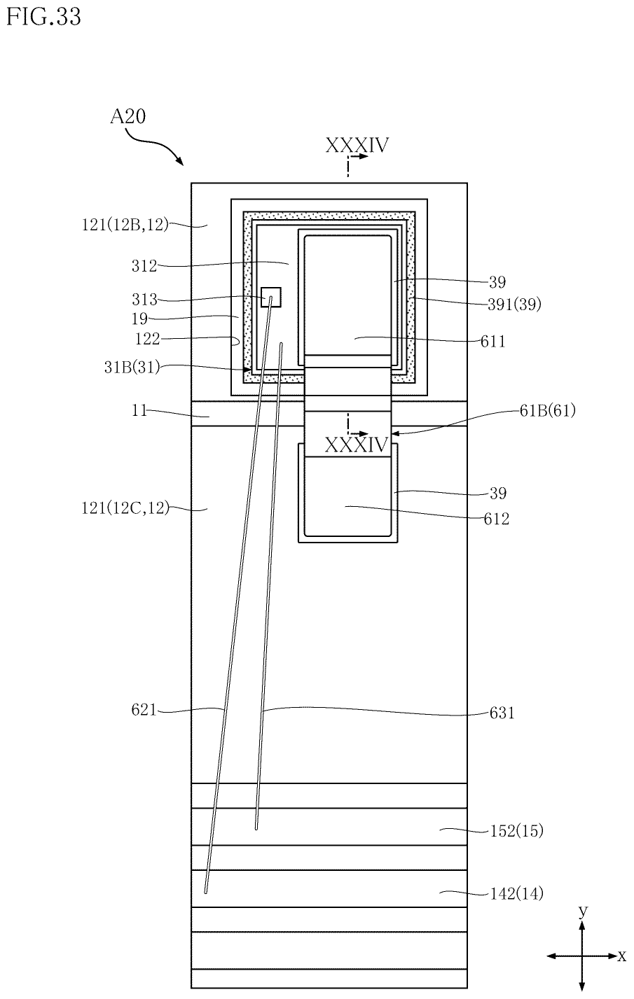

As shown in FIGS. 31 and 33, each of the conductive members 61 has a first bond portion 611 and a second bond portion 612. The first bond portion 611 is conductively bonded to the second electrode 312 of one of the semiconductor elements 31 via a bonding layer 39. The bonding layer 39 is solder, for example. The second bond portion 612 is conductively bonded to the second conductive layer 12B or the third conductive layer 12C among the conductive layers 12 via a bonding layer 39.

As shown in FIGS. 25 and 26, the plurality of conductive members 61 include a plurality of first conductive members 61A and a plurality of second conductive members 61B. As shown in FIG. 31, the first conductive members 61A are individually conductively bonded to the second electrodes 312 of the first elements 31A and the second conductive layer 12B. Thus, the second electrodes 312 of the first elements 31A are electrically connected to the second conductive layer 12B. Thus, the second electrodes 312 of the first elements 31A are electrically connected to the output terminal 22. As shown in FIG. 33, the second conductive members 61B are individually conductively bonded to the second electrodes 312 of the second elements 31B and the third conductive layer 12C. Thus, the second electrodes 312 of the second elements 31B are electrically connected to the third conductive layer 12C. Thus, the second electrodes 312 of the second elements 31B are electrically connected to the second input terminal 21B.

The first gate wires 621 and the first detection wires 631 individually conductively bonded to the first elements 31A will be described based on FIG. 31. The first gate wires 621 are individually conductively bonded to the gate electrodes 313 of the first elements 31A and the first gate wiring 141. The first detection wires 631 are individually conductively bonded to the second electrodes 312 of the first elements 31A and the first detection wiring 151.

The first gate wires 621 and the first detection wires 631 individually conductively bonded to the second elements 31B will be described based on FIG. 33. The first gate wires 621 are individually conductively bonded to the gate electrodes 313 of the second elements 31B and the second gate wiring 142. The first detection wires 631 are individually conductively bonded to the second electrodes 312 of the second element 31B and the second detection wiring 152.

As shown in FIGS. 25 and 26, the semiconductor device A20 further includes a pair of second gate wires 622. The pair of second gate wires 622 are individually conductively bonded to the gate terminals 24 and the gate wirings 14. The second gate wires 622 are made of aluminum, for example.

As shown in FIG. 26, one of the second gate wires 622 is conductively bonded to the first gate terminal 24A and the first gate wiring 141. Thus, the first gate terminal 24A is electrically connected to the gate electrodes 313 of the first elements 31A. As shown in FIG. 25, the other one of the second gate wires 622 is conductively bonded to the second gate terminal 24B and the second gate wiring 142. Thus, the second gate terminal 24B is electrically connected to the gate electrodes 313 of the second elements 31B.

As shown in FIGS. 25 and 26, the semiconductor device A20 further includes a pair of second detection wires 632. The second detection wires 632 are bonded to the detection terminals 25 and the detection wirings 15. The second detection wires 632 are made of aluminum, for example.

As shown in FIG. 26, one of the second detection wires 632 is conductively bonded to the first detection terminal 25A and the first detection wiring 151. Thus, the first detection terminal 25A is electrically connected to the second electrodes 312 of the first elements 31A. As shown in FIG. 25, the other one of the second detection wires 632 is conductively bonded to the second detection terminal 25B and the second detection wiring 152. Thus, the second detection terminal 25B is electrically connected to the second electrodes 312 of the second elements 31B.

As shown in FIGS. 27 and 28, the case 70 supports the heat dissipation member 75. The case 70 houses the insulating layer 11, the conductive layers 12, the heat dissipation layer 13, the semiconductor elements 31, and the sealing resin 50. The case 70 is electrically insulating. The case 70 is made of a material containing a heat-resistant resin, such as PPS (polyphenylene sulfide). The case 70 has a pair of first side walls 711, a pair of second side walls 712, a plurality of mount portions 72, an input terminal base 73, and an output terminal base 74.

As shown in FIGS. 19 and 20, the pair of first side walls 711 are spaced apart from each other in the second direction X. Each of the first side walls 711 is along the third direction y and the first direction z and in contact with the heat dissipation member 75 at one end in the first direction Z.

As shown in FIGS. 19 and 20, the pair of second side walls 712 are spaced apart from each other in the third direction y. Each of the second side walls 712 is along the second direction x and the first direction z and in contact with the heat dissipation member 75 at one end in the first direction z. The opposite ends in the second direction x of each second side wall 712 are connected to the first side walls 711. The first gate terminal 24A, the first detection terminal 25A, the input current detection terminal 26, and the pair of thermistor terminals 27 are disposed inside one of the second side walls 712. The second gate terminal 24B and the second detection terminal 25B are disposed inside the other one of the second side walls 712. As shown in FIGS. 25 and 26, the ends of these terminals that are closer to the insulating layer 11 in the first direction z are supported on the pair of second side walls 712.

As shown in FIGS. 19, 25, and 26, the mount portions 72 are provided at four corners of the case 70 as viewed in the first direction z. The heat dissipation member 75 is in contact with the lower surface of the mount portions 72. Each of the mount portions 72 is formed with a mounting hole 721 penetrating in the first direction z. The semiconductor device A20 can be attached to a heat sink by inserting fastening members, such as bolts, into the mounting holes 721.

As shown in FIGS. 19, 22, and 25, the input terminal base 73 protrudes outward in the second direction x from one of the first side walls 711. The input terminal base 73 supports the input terminals 21. The input terminal base 73 includes a first terminal base 731 and a second terminal base 732. The first terminal base 731 and the second terminal base 732 are spaced apart from each other in the third direction y. The first terminal base 731 supports the first input terminal 21A. The external connection part 211 of the first input terminal 21A is exposed from the first terminal base 731. The second terminal base 732 supports the second input terminal 21B. The external connection part 211 of the second input terminal 21B is exposed from the second terminal base 732. A plurality of grooves 733 extending in the second direction x are formed between the first terminal base 731 and the second terminal base 732. As shown in FIGS. 27 and 29, a pair of nuts 734 and a pair of intermediate members 735 are disposed inside the first terminal base 731 and the second terminal base 732. The intermediate members 735 are located on the side on which the insulating layer 11 is located with respect to the nuts 734 in the first direction z and held in contact with the nuts 734. One of the intermediate members 735 supports the external connection part 211 and the intermediate part 213 of the first input terminal 21A. The other intermediate member 735 supports the external connection part 211 and the intermediate part 213 of the second input terminal 21B. Each of the intermediate members 735 is partially exposed from the input terminal base 73. The pair of nuts 734 correspond to the pair of connection holes 211A provided in the first input terminal 21A and the second input terminal 21B. The fastening members, such as bolts, inserted in the connection holes 211A mesh with the nuts 734.

As shown in FIGS. 19, 23, and 26, the output terminal base 74 protrudes outward in the second direction x from the other one of the first side walls 711. The output terminal base 74 supports the output terminal 22. The output terminal base 74 includes a first terminal base 741 and a second terminal base 742. The first terminal base 741 and the second terminal base 742 are spaced apart from each other in the third direction y. The first terminal base 741 supports the first output terminal 22A of the output terminal 22. The external connection part 221 of the first output terminal 22A is exposed from the first terminal base 741. The second terminal base 742 supports the second output terminal 22B of the output terminal 22. The external connection part 221 of the second output terminal 22B is exposed from the second terminal base 742. A plurality of grooves 743 extending in the second direction x are formed between the first terminal base 741 and the second terminal base 742. As shown in FIGS. 27 and 30, a pair of nuts 744 and a pair of intermediate members 745 are disposed inside the first terminal base 741 and the second terminal base 742. The intermediate members 745 are located on the side on which the insulating layer 11 is located with respect to the nuts 744 in the first direction z and held in contact with the nuts 744. One of the intermediate members 745 supports the external connection part 221 and the intermediate part 223 of the first output terminal 22A. The other intermediate member 745 supports the external connection part 221 and the intermediate part 223 of the second output terminal 22B. Each of the intermediate members 745 is partially exposed from the output terminal base 74. The pair of nuts 744 correspond to the pair of connection holes 221A provided in the first output terminal 22A and the second output terminal 22B. The fastening members, such as bolts, inserted in the connection holes 221A mesh with the nuts 744.

As shown in FIGS. 27 and 28, the sealing resin 50 covers the semiconductor elements 31 while being housed in the case 70. The sealing resin 50 is electrically insulating. The sealing resin 50 is made of silicone gel, for example. Alternatively, the sealing resin 50 may be made of an epoxy resin. A part of the sealing resin 50 is located inside the recesses 19 provided in first conductive layer 12A and the second conductive layer 12B of the conductive layers 12.

Next, the effects of the semiconductor device A20 will be described.

The semiconductor device A20 includes the conductive layer 12 bonded to the insulating layer 11, the semiconductor elements 31 bonded to the obverse surface 121 of the conductive layer 12, and the bonding layers 39 bonding the obverse surface 121 and the semiconductor elements 31. The conductive layer 12 has recesses 19 that are recessed from the obverse surface 121. Each bonding layer 39 includes a first portion 391 located between the semiconductor element 31 and the recess 19 as viewed in the first direction z. The first portion 391 covers the obverse surface 121. In the semiconductor device A20 having such a configuration again, the accuracy in the bond positions of the semiconductor elements 31 to the conductor layer 12 can be improved. Further, the semiconductor device A20 has a configuration in common with the semiconductor device A10, thereby achieving the same effect as the semiconductor device A10.

The semiconductor device A20 further includes the first input terminal 21A electrically connected to the first elements 31A and the second input terminal 21B electrically connected to the second elements 31B. The first input terminal 21A and the second input terminal 21B are next to each other. Thus, when a voltage is applied to the first input terminal 21A and the second input terminal 21B, a mutual inductance is generated between the first input terminal 21A and the second input terminal 21B. Therefore, the parasitic inductance of the semiconductor device A20 can be reduced.

The semiconductor device A20 further includes a heat dissipation member 75 located opposite to the insulating layer 11 with respect to the heat dissipation layer 13. The heat dissipation layer 13 is bonded to the heat dissipation member 75. The dimension of the heat dissipation member 75 in the first direction z is greater than the dimension of the heat dissipation layer 13 in the first direction z. Such a configuration improves the heat dissipation of the semiconductor device 20.

The present disclosure is not limited to the foregoing embodiments. Various modifications in design may be made freely in the specific structure of each part of the present disclosure.

The present disclosure includes the embodiments described in the following clauses.

### Clause 1.

A semiconductor device comprising:
an insulating layer;
a conductive layer that includes an obverse surface facing away from the insulating layer in a first direction and that is bonded to the insulating layer;
a heat dissipation layer located opposite to the conductive layer with respect to the insulating layer and bonded to the insulating layer;
a semiconductor element bonded to the obverse surface; and
a bonding layer that bonds the obverse surface and the semiconductor element, wherein
the conductive layer is formed with a recess that is recessed from the obverse surface,
the bonding layer includes a first portion located between the semiconductor element and the recess as viewed in the first direction, and
the first portion covers the obverse surface.

### Clause 2.

The semiconductor device according to clause 1, wherein the conductive layer includes an inner surface connected to the obverse surface and defining the recess, and
the first portion reaches a boundary between the inner surface and the obverse surface.

### Clause 3.

The semiconductor device according to clause 2, wherein the inner surface includes a first interior face and a second interior face that face each other in a direction orthogonal to the first direction, and
the first interior face and the second interior face approach each other as extending from the obverse surface toward the insulating layer.

### Clause 4.

The semiconductor device according to clause 3, wherein the inner surface includes a third interior face connected to the first interior face and the second interior face, and
the third interior face faces a same side as the obverse surface in the first direction.

### Clause 5.

The semiconductor device according to clause 3 or 4, wherein each of the first interior face and the second interior face is curved toward inside of the conductive layer.

### Clause 6.

The semiconductor device according to any one of clauses 2 to 5, wherein the recess extends in a direction crossing a periphery of the semiconductor element as viewed in the first direction.

### Clause 7.

The semiconductor device according to any one of clauses 2 to 5, wherein the recess extends along a periphery of the semiconductor element as viewed in the first direction.

### Clause 8.

The semiconductor device according to any one of clauses 2 to 5, wherein the recess surrounds the semiconductor element as viewed in the first direction.

### Clause 9.

The semiconductor device according to clause 8, wherein the conductive layer includes a seat portion surrounded by the recess, and
a cross-sectional area of the seat portion orthogonal to the first direction increases from the obverse surface toward the insulating layer.

### Clause 10.

The semiconductor device according to clause 6 or 7, wherein the recess includes a first recess and a second recess separated from the first recess, and
the first recess and the second recess are located opposite to each other with respect to the semiconductor element.

### Clause 11.

The semiconductor device according to clause 10, wherein each of the first recess and the second recess is located closest to one of four corners of the semiconductor element.

### Clause 12.

The semiconductor device according to clause 7 or 8, wherein, as viewed in the first direction, the periphery of the semiconductor element includes a first edge, and a second edge extending in a direction different from the first edge and connected to the first edge,
the recess includes a first groove extending along the first edge, and a second groove extending along the second edge and connected to the first groove, and
as viewed in the first direction, the first groove and an extension line of the second edge cross each other, while the second groove and an extension line of the first edge cross each other.

### Clause 13.

The semiconductor device according to any one of clauses 2 to 12, wherein the semiconductor element includes a first electrode facing the obverse surface and a second electrode located opposite to the first electrode in the first direction, and
the first electrode is conductively bonded to the obverse surface via the bonding layer.

### Clause 14.

The semiconductor device according to clause 13, further comprising a terminal electrically connected to the second electrode,
wherein the terminal is spaced apart from the conductive layer as viewed in the first direction.

### Clause 15.

The semiconductor device according to any one of clauses 2 to 14, further comprising a sealing resin covering the semiconductor element,
wherein a part of the sealing resin is located inside the recesses.

### Clause 16.

The semiconductor device according to clause 15, wherein the sealing resin includes a bottom surface facing away from the obverse surface in the first direction, and
the heat dissipation layer is exposed from the bottom surface.

### Clause 17.

The semiconductor device according to clause 15 or 16, further comprising an IC electrically connected to the semiconductor element,
wherein the IC is covered with the sealing resin.

REFERENCE NUMERALS

| | |
|---|---|
| A10, A20: Semiconductor device | 11: Insulating layer |
| 12: Conductive layer | 12A: First conductive layer |
| 12B: Second conductive layer | 12C: Third conductive layer |
| 121: Obverse surface | 121A: Boundary |
| 122: Inner surface | 122A: First interior face |
| 122B: Second interior face | 122C: Third interior face |
| 123: Seat portion | 124: Bond portion |
| 13: Heat dissipation layer | 14: Gate wiring |
| 141: First gate wiring | 142: Second gate wiring |
| 15: Detection wiring | 151: First detection wiring |
| 152: Second detection wiring | 16: Pad |
| 19: Recess | 19A: First recess |
| 19B: Second recess | 19C: Third recess |
| 19D: Fourth recess | 191: First groove |
| 192: Second groove | 21: Input terminal |
| 21A: First input terminal | 21B: Second input terminal |
| 211: External connection part | 211A: Connection hole |
| 212: Internal connection part | 213: Intermediate part |
| 213A: Base portion | 213B: Standing portion |
| 22: Output terminal | 22A: First output terminal |
| 22B: Second output terminal | 22C: Third output terminal |
| 221: External connection part | 221A: Connection hole |
| 222: Internal connection part | 223: Intermediate part |
| 223A: Base portion | 223B: Standing portion |
| 23: Control terminal | 231: Pad section |
| 232: Power supply section | 233: First control section |
| 234: Second control section | 235: Dummy section |
| 24: Gate terminal | 24A: First gate terminal |
| 24B: Second gate terminal | 25: Detection terminal |
| 25A: First detection terminal | |
| 25B: Second detection terminal | |
| 26: Input current detection terminal | |
| 27: Thermistor terminal | |
| 29: Dummy terminal | 31: Semiconductor element |
| 31A: First element | 31B: Second element |
| 311: First electrode | 312: Second electrode |
| 313: Gate electrode | 314: Periphery |
| 314A: First periphery | 314B: Second periphery |
| 33: IC | 33A: First IC |
| 33B: Second IC | 34: Diode |
| 35: Thermistor | 39: Bonding layer |
| 391: First portion | 391A: End surface |
| 41: First wire | 42: Second wire |
| 43: Third wire | 44: Fourth wire |
| 45: Fifth wire | 46: Sixth wire |
| 50: Sealing resin | 51: Top surface |
| 52: Bottom surface | 53: First side surface |
| 54: Second side surface | 55: Dented portion |
| 61: Conductive member | 61A: First conductive member |
| 61B: Second conductive member | 611: First bond portion |
| 612: Second bond portion | 621: First gate wire |
| 622: Second gate wire | 631: First detection wire |
| 632: Second detection wire | 64: Input current detection wire |
| 65: Thermistor wire | 70: Case |
| 711: First side wall | 712: Second side wall |
| 72: Mount portion | 721: Mounting hole |
| 73: Input terminal base | 731: First terminal base |
| 732: Second terminal base | 733: Groove |
| 734: Nut | 735: Intermediate member |
| 74: Output terminal base | 741: First terminal base |
| 742: Second terminal base | 744: Groove |
| 745: Nut | 745: Intermediate member |
| 75: Heat dissipation member | z: First direction |
| x: Second direction | y: Third direction |

1. A semiconductor device comprising:
an insulating layer;
a conductive layer that includes an obverse surface facing away from the insulating layer in a first direction and that is bonded to the insulating layer;
a heat dissipation layer located opposite to the conductive layer with respect to the insulating layer and bonded to the insulating layer;
a semiconductor element bonded to the obverse surface; and
a bonding layer that bonds the obverse surface and the semiconductor element, wherein
the conductive layer is formed with a recess that is recessed from the obverse surface,
the bonding layer includes a first portion located between the semiconductor element and the recess as viewed in the first direction, and
the first portion covers the obverse surface.

2. The semiconductor device according to claim 1, wherein the conductive layer includes an inner surface connected to the obverse surface and defining the recess, and
the first portion reaches a boundary between the inner surface and the obverse surface.

3. The semiconductor device according to claim 2, wherein the inner surface includes a first interior face and a second interior face that face each other in a direction orthogonal to the first direction, and
the first interior face and the second interior face approach each other as extending from the obverse surface toward the insulating layer.

4. The semiconductor device according to claim 3, wherein the inner surface includes a third interior face connected to the first interior face and the second interior face, and
the third interior face faces a same side as the obverse surface in the first direction.

5. The semiconductor device according to claim 3, wherein each of the first interior face and the second interior face is curved toward inside of the conductive layer.

6. The semiconductor device according to claim 2, wherein the recess extends in a direction crossing a periphery of the semiconductor element as viewed in the first direction.

7. The semiconductor device according to claim 2, wherein the recess extends along a periphery of the semiconductor element as viewed in the first direction.

8. The semiconductor device according to claim 2, wherein the recess surrounds the semiconductor element as viewed in the first direction.

9. The semiconductor device according to claim 8, wherein the conductive layer includes a seat portion surrounded by the recess, and
a cross-sectional area of the seat portion in a direction orthogonal to the first direction increases from the obverse surface toward the insulating layer.

10. The semiconductor device according to claim 6, wherein the recess includes a first recess and a second recess separated from the first recess, and
the first recess and the second recess are located opposite to each other with respect to the semiconductor element.

11. The semiconductor device according to claim 10, wherein each of the first recess and the second recess is located closest to one of four corners of the semiconductor element.

12. The semiconductor device according to claim 7, wherein, as viewed in the first direction, the periphery of the semiconductor element includes a first edge, and a second edge extending in a direction different from the first edge and connected to the first edge,
the recess includes a first groove extending along the first edge, and a second groove extending along the second edge and connected to the first groove, and
as viewed in the first direction, the first groove and an extension line of the second edge cross each other, while the second groove and an extension line of the first edge cross each other.

13. The semiconductor device according to claim 2, wherein the semiconductor element includes a first electrode facing the obverse surface and a second electrode located opposite to the first electrode in the first direction, and
the first electrode is conductively bonded to the obverse surface via the bonding layer.

14. The semiconductor device according to claim 13, further comprising a terminal electrically connected to the second electrode,
wherein the terminal is spaced apart from the conductive layer as viewed in the first direction.

15. The semiconductor device according to claim 2, further comprising a sealing resin covering the semiconductor element,
wherein a part of the sealing resin is located inside the recesses.

16. The semiconductor device according to claim 15, wherein the sealing resin includes a bottom surface facing away from the obverse surface in the first direction, and
the heat dissipation layer is exposed from the bottom surface.

17. The semiconductor device according to claim 15, further comprising an IC electrically connected to the semiconductor element,
wherein the IC is covered with the sealing resin.
